(19) United States
(12) Patent Application Publication
(10) Pub. No.: US 2026/0198166 A1
(43) Pub. Date: Jul. 9, 2026

(54) PHOTOVOLTAIC MODULES AND METHODS OF MAKING SAME

(71) Applicant: Energy Materials Corporation, Rochester, NY (US)

(72) Inventors: Matthew Davis, East Rochester, NY (US); Scott Kenneth Christensen, North Chili, NY (US)

(21) Appl. No.: 19/128,251

(22) PCT Filed: Nov. 7, 2023
(86) PCT No.: PCT/US23/78892

§ 371 Date: May 8, 2025

Related U.S. Application Data
(60) Provisional application No. 63/424,247, filed on Nov. 10, 2022.

(51) Int. Cl. H10K 30/40; H10K 39/12

(52) U.S. Cl. CPC H10K 30/40; H10K 39/12

(57) ABSTRACT

A method of making a photovoltaic module from a module precursor structure is provided. The module precursor structure includes a substrate, a bottom electrode overlaying the substrate, and a photoactive layer overlaying the bottom electrode, wherein the photoactive layer includes at least a perovskite absorber layer, and a top electrode overlaying the photoactive layer. At least one of the top and bottom electrodes is a transparent electrode. A megascribe is formed along a first dimension of the module precursor structure to define first and second photovoltaic cells. The megascribe is formed by removing the top electrode and photoactive layer in an upper scribe portion of the megascribe, and removing the bottom electrode in a lower scribe portion of the megascribe.

### CROSS-REFERENCE TO RELATED APPLICATIONS

This application claims the benefit of priority of U.S. Provisional Application No. 63/424,247 filed Nov. 10, 2022, the entire contents of which is incorporated by reference in its entirety for all purposes.

### TECHNICAL FIELD

The present disclosure relates to perovskite photovoltaic modules having photovoltaic cells connected in series, and in particular, to methods of making series interconnections.

### BACKGROUND

Since their first report in 2009, rapid improvements have enabled perovskite solar cells (PSCs) to become a promising technology for converting light to electricity as part of optoelectronic devices. To date, the power conversion efficiencies (PCEs) of solution-processed PSCs have been certified above 25 percent, which is higher than the current dominant photovoltaic technology based on multi-crystalline silicon. Whereas crystalline silicon is rigid, brittle, and requires costly, energy-intensive fabrication procedures, perovskites are flexible, easily processed at low temperatures, and up to a thousand times thinner. Furthermore, perovskites are solution-processable, which enables their manufacture with scalable, low-cost methods. These attributes open new opportunities to integrate solar power creatively and inexpensively into previously inaccessible markets, such as electric vehicles and buildings. PSCs also have the important advantage of maintaining acceptable PCE as the temperature increases, unlike silicon-based solar cells, which exhibit significant power loss in typical operating environments. The manufacturing and PCE advantages of PSCs have put them on the path to be the next generation technology for utility, commercial, and residential photovoltaic applications.

Most top performing PSCs reported in the literature have been fabricated by lab-scale, spin-coating methods, which are unsuitable for high throughput and scalable module production. Forming high-performing, uniform, and defect-free multilayer structures on flexible substrates to make PSCs in a cost-effective manner remains a great challenge. Some of this complexity is due to the complexity of depositing and drying a perovskite solution with high-speed production equipment, but other layers can be challenging as well. Some non-limiting factors to consider in the manufacture of multilayer PSCs may include the adhesion of one layer to another, the chemical compatibility of a coating solution with an underlying layer, thermal treatments and compatibility of such with other layers, surface energy or structures and their effect on coatability, layer flexibility, thermal expansion properties, and optical properties, just to name a few.

Commercial photovoltaic (PV) modules usually include a plurality of PV cells that are connected in series. Such series connection is often referred to as the “interconnect”. Conventional interconnects are typically fabricated using a so-called 3-scribe method using laser etching. An example of such a fabrication process is illustrated in FIG. 7. In step 781, sometimes referred to as a P1 scribe, laser etching is used to form a first scribe 741 in a bottom electrode layer 704 that is disposed over a substrate 701. After step 781, an absorber/active material layer 706 is deposited over the structure, typically in a deposition apparatus separate from the laser etching apparatus. This is followed by step 782, sometimes referred to as a P2 scribe, where laser etching is used to form a second scribe 742 in the absorber layer 706 but not through bottom electrode 704. After step 782, a top electrode layer 708 is deposited over the structure, typically in a deposition apparatus separate from the laser etching apparatus. This is followed by step 783, sometimes referred to as a P3 scribe, where laser etching is used to form a third scribe 743 through the top electrode layer 708 and the absorber layer 706, but not through bottom electrode layer 704.

There are several drawbacks to the traditional 3-scribe process. First, laser etching equipment can be very expensive. Along a manufacturing line three separate sets of laser equipment may be needed which is costly. Alternatively, structures may be returned to a common laser etcher after deposition of the absorber layer for P2 and again after deposition of the top electrode layer for P3. This can seriously impact manufacturing takt time which also adds cost. Further, the laser etching steps require careful alignment to make sure P2 is properly spaced from P1 and P3 is properly spaced from P2. The need for alignment can slow production, add cost, and introduce sources for defects. In addition to the forgoing, the traditional 3-scribe process may also result in a significant amount of “inactive area” width 785 where the PV module does not produce electricity, thus reducing the areal power production of the module. The width of each inactive area of a traditional 3-scribe device may in some cases be 250 μm or even higher. Each laser etch step requires a certain level of manufacturing tolerance which limits how small this inactive area can be made. The traditional 3-scribe process can leave exposed sidewalls of the absorber layer. This may be tolerable for some PV structures, but such exposed sidewalls may lead to degradation of perovskite-based PV structures. The P2 sidewall, in particular, may degrade the conductive contacting layer.

High efficiency PSCs benefit from electrodes that have low electrical resistance and where one or both have high optical transparency, but such electrodes can be difficult to produce at high manufacturing speeds in a manner compatible with other layers of the PSC and other manufacturing steps, such as forming interconnects. Low resistance electrodes are particularly desired for high area devices where photogenerated currents may need to travel a significant distance to current collectors or other device components. Higher resistance across a long path can result in an unacceptable power efficiency loss. The challenges are further heightened when both electrodes are transparent, such as in bifacial photovoltaic structures. Bifacial solar cells can receive light from the front or back and generate electricity.

Despite research into various approaches, PVs based primarily on perovskites have yet to make a large market impact due at least in part to some of the unresolved problems noted above.

### SUMMARY

There remains a desire for PSC devices that can be reliably manufactured at large scale at high speeds, at low cost, have high PCEs, and that can be made having large sizes or surface areas without unacceptable power loss.

In accordance with an embodiment of this disclosure, a method of making a photovoltaic module from a module precursor structure is provided. The module precursor structure includes a substrate, a bottom electrode overlaying the substrate, a photoactive layer overlaying the bottom electrode, wherein the photoactive layer comprising at least a perovskite absorber layer, and a top electrode overlaying the photoactive layer. At least one of the top and bottom electrodes is a transparent electrode. A megascribe is formed along a first dimension of the module precursor structure to define first and second photovoltaic cells. The megascribe is formed by removing the top electrode and photoactive layer in an upper scribe portion of the megascribe, and removing the bottom electrode in a lower scribe portion of the megascribe. A first insulating material is formed along an edge of the first photovoltaic cell defined by the megascribe, and a second insulating material is formed along an edge of the second photovoltaic cell defined by the megascribe. At least a portion of the bottom electrode corresponding to the second photovoltaic cell is not covered by either the first or second insulating materials. A series connection is made between the first and second photovoltaic cells by depositing an electrically conductive connector onto a portion of the top electrode of the first photovoltaic cell, over the first insulating material, and onto the portion of the bottom electrode of the second photovoltaic cell.

The present disclosure provides for PV devices and methods of their manufacture that may have one or more of the following advantages relative to conventional PV technology: improved manufacturing scalability, shorter manufacturing takt times, reduced manufacturing costs, simplified manufacturing processes; reduced manufacturing defects; more reproducible manufacturing processes; reduced environmental impact; improved areal PCE; lower resistance electrodes; electrodes with higher optical transparency; increased physical durability or increased lifetime.

### BRIEF DESCRIPTION OF DRAWINGS

FIG. 1A is a top view of a non-limiting example of a perovskite PV module according to some embodiments.

FIG. 1B is an enlarged top view of area B of the perovskite PV module from FIG. 1A.

FIG. 1C is a cross-sectional view of the perovskite PV module along cutline C-C of FIG. 1B.

FIG. 1D is a cross-sectional view of the perovskite PV module along cutline D-D of FIG. 1B.

FIG. 1E is a cross-sectional view of the perovskite PV module like FIG. 1C to illustrate additional features of the perovskite PV module according to some embodiments.

FIG. 2A is a top view of a non-limiting example of a module precursor structure according to some embodiments.

FIG. 2B is an enlarged top view of area B of the module precursor structure from FIG. 2A.

FIG. 2C is a cross-sectional view of the module precursor structure along cutline C-C of FIG. 2B.

FIG. 2D is a cross-sectional view of the module precursor structure along cutline D-D of FIG. 2B.

FIGS. 2E-2F are cross-sectional views of a non-limiting example of forming a megascribe in a module precursor structure according to some embodiments.

FIGS. 2G-2H are cross-sectional views of a non-limiting example of forming a megascribe in a module precursor structure according to some embodiments.

FIGS. 2I-2J are cross-sectional views of a non-limiting example of forming a megascribe in a module precursor structure according to some embodiments.

FIGS. 2K-2L are cross-sectional views of non-limiting examples of megascribes formed in a module precursor structure according to some embodiments.

FIG. 2M is a cross-sectional view of a non-limiting example of forming insulating materials according to some embodiments.

FIG. 2N is a cross-sectional view of a non-limiting example of forming an electrically conductive connector and forming a PV module according to some embodiments.

FIG. 3A is a top view of a non-limiting example of a module precursor structure according to some embodiments.

FIG. 3B is an enlarged top view of area B of the module precursor structure from FIG. 3A.

FIG. 3C is a cross-sectional view of the module precursor structure along cutline C-C of FIG. 3B.

FIG. 3D is a cross-sectional view of a non-limiting example of a PV module made from the module precursor structure from FIG. 3C according to some embodiments.

FIG. 4 is a flow diagram of some non-limiting steps for making a PV module according to some embodiments.

FIG. 5 is a cross-sectional view of a non-limiting example of a perovskite PV structure according to some embodiments.

FIG. 6 is a cross-sectional schematic of a non-limiting example of an interconnect processing station according to some embodiments.

FIG. 7 is a series of cross-sectional views of forming an interconnect according to the prior art.

### DETAILED DESCRIPTION

It is to be understood that the drawings are for purposes of illustrating the concepts of the disclosure and may not be to scale. Terms like “overlaying”, “over” or the like include, but do not necessarily require, direct contact (unless such direct contact is noted or clearly required for functionality). Additional details of certain embodiments of the present application may be found in U.S. Pat. Nos. 11,108,007, 11,342,130, U.S. Application Publication No. 2020/0377532, U.S. Application Publication No. 2022/0238807, PCT Application No. PCT/US23/34120, PCT Application No. PCT/US23/34136, and PCT Application No. PCT/US23/34147, the entire contents of which are incorporated herein by reference for all uses.

A perovskite photovoltaic structure is intended to receive light (typically visible, IR, or UV light) and convert it into electricity. As such, various layers and features may need to be reasonably transparent to this light to ensure that an appropriate amount reaches the perovskite layer(s). Herein, unless otherwise noted, the terms “transparent”, “transparency”, “transmissivity” or the like, are generally relative to the target wavelength or wavelength range for conversion to electricity. This target wavelength or wavelength range may be different for different systems. In some embodiments, the target wavelength range may correspond to the solar radiation spectrum or a portion thereof. In some cases, the target wavelength range may correspond to the visible light spectrum or a portion thereof. In some cases, the target wavelength range may correspond to the infrared or UV spectrum, or a portion thereof. In some embodiments, the target wavelength range may be defined as a particular wavelength, e.g., 400 nm, 450 nm, 500 nm, 550 nm, 600 nm, 650 nm, 700 nm, or 750 nm, or any other wavelength of interest in the IR, visible, or UV portions of the spectrum intended for energy conversion. In some cases, a target wavelength range may be defined as an explicit range, e.g., 400-425 nm, 425-450 nm, 450-475 nm, 475-500 nm, 500-525 nm, 525-575 nm, 575-600 nm, 600-625 nm, 625-650 nm, 650-675 nm, 675-700 nm, 700-725 nm, 725-750 nm, or any combination of ranges thereof, or any other wavelength range of interest.

In some embodiments, something (e.g., a layer, a component, a structure, or the like) that is “transparent” transmits at least 50% of incident radiation within the target wavelength range, i.e., a transmittance (% T) of 50%. Something that is considered light transmissive generally transmits at least 10% of incident radiation within the target wavelength range. Transmittivities in the range of 10% up to 50% may be considered partially transparent. A light-transmissive component, layer, or structure may be either transparent or partially transparent.

Besides the light-absorbing properties of a layer, a component, a structure, or the like, its apparent transparency may in some cases be affected by refractive index mismatches, surface structures, or other factors that may result in reflective losses and/or light scattering. Another way to describe transparency is in terms of absorptance (% A). In some embodiments, something that is “transparent” may have an absorptance of 50% or less with respect to incident radiation within the target wavelength range. Something that is considered light transmissive may have an absorptance of 90% or less of incident radiation within the target wavelength range. Absorptances in a range of 50% up to 90% may be considered partially transparent.

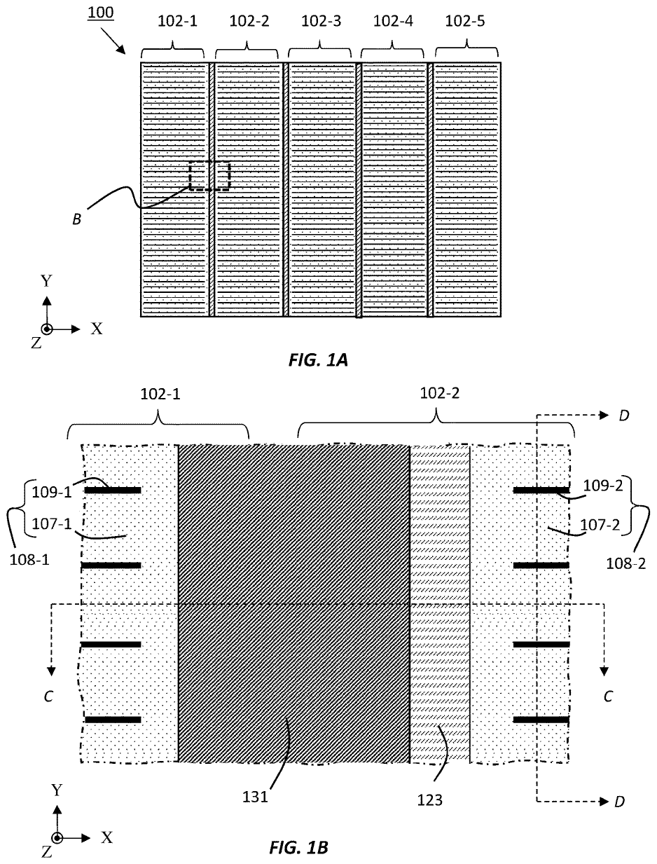

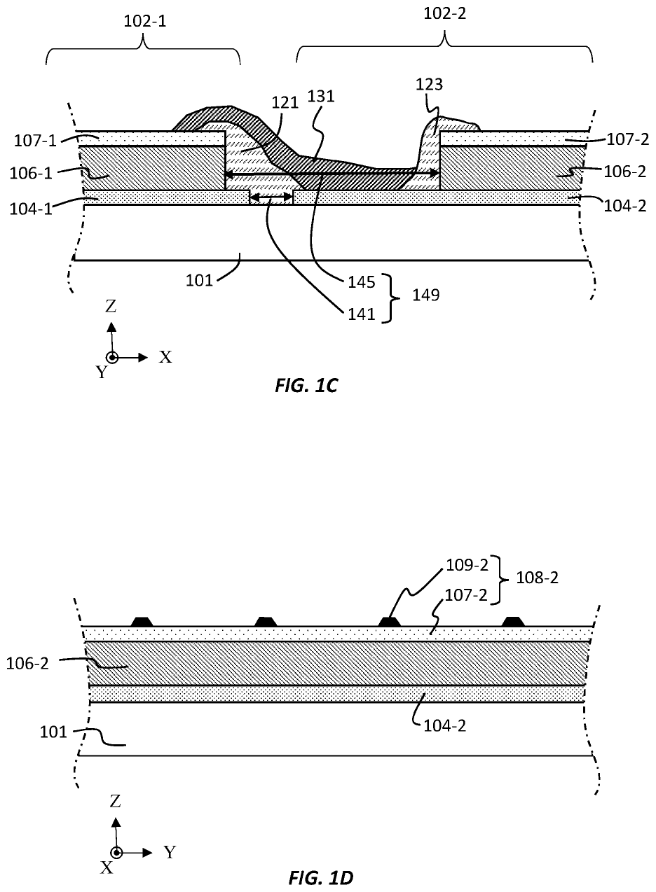

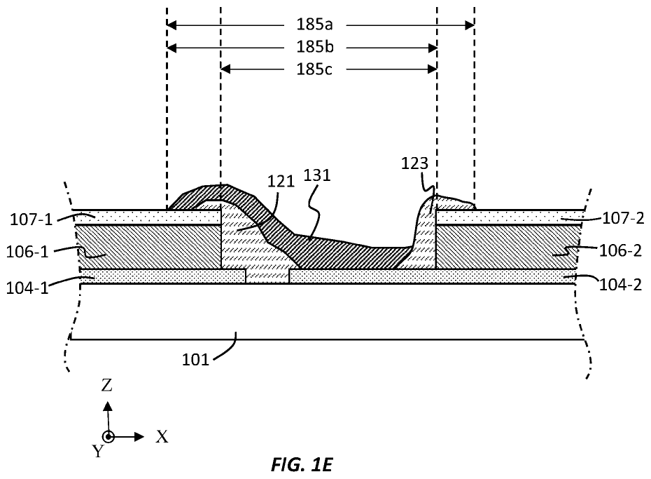

FIGS. 1A-1E are various views of a perovskite-containing PV module according to some embodiments. In particular, FIG. 1A is a top view of a perovskite PV module, FIG. 1B is an enlarged top view of area B from FIG. 1A, FIG. 1C is a cross-sectional view along cutline C-C of FIG. 1B, and FIG. 1D is a cross-sectional view along cutline D-D of FIG. 1B. FIG. 1E is like FIG. 1C and used to illustrate some additional properties or features of the PV module as described below. For added perspective, XYZ coordinate axes are also shown.

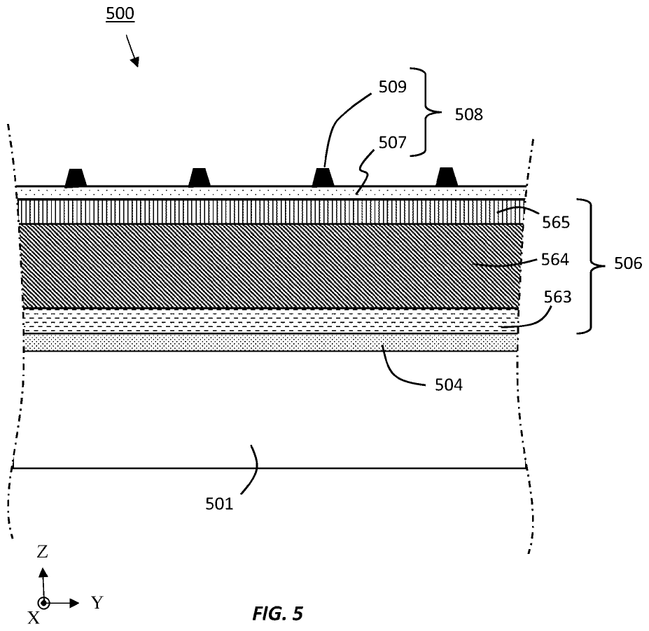

Perovskite PV module 100 may include two or more PV cells connected in series, e.g., first PV cell 102-1, second PV cell 102-2, third PV cell 102-3, fourth PV cell 102-4, and fifth PV cell 102-5. A PV module may contain more or fewer PV cells than what is shown in FIG. 1A. A series interconnect region between first and second PV cells, 102-1 and 102-2, are described with reference to FIGS. 1B-1D. The two or more PV cells may be provided over a common substrate 101. Each PV cell 102-1, 102-2 may include a photoactive layer 106-1, 106-2 disposed over bottom electrode 104-1, 104-2. Each photoactive layer may have a multilayer structure as described herein with respect to FIG. 5, but at least includes a perovskite absorber layer. Each PV cell includes a top electrode 108-1, 108-2. One or both of the top and bottom electrodes may be transparent. In some preferred embodiments, at least the top electrode is transparent. For example, top electrodes 108-1 and 108-2 may be transparent and the PV module is designed to receive radiation or sunlight through the top, i.e., through the top electrodes. The bottom electrode may be reflective or absorptive with respect to target radiation, or alternatively, may also be transparent or partially transparent for use in bifacial PV module applications. In some cases, an electrode may be formed of a single material layer or alternatively include multiple material layers. In some embodiments, an electrode may include a composite conductor having two or more materials or layers. For example, top electrode 108-1, 108-2 may be a transparent composite conductor having a transparent top conductor layer 107-1, 107-2 disposed over the photoactive layer 106-1, 106-2 and a top set of metal lines 109-1, 109-2 overlaying the top conductor layer 107-1, 107-2. In some cases, the physical, electrical, or compositional properties of the first and second PV cells may optionally be different, but preferably, they may be approximately the same. Additional details regarding materials and methods for forming PV cells are found elsewhere herein.

The first and second PV cells are separated by a megascribe 149 extending along a first dimension that may be generally parallel to the Y axis of the present FIGS. 1A-1E. Megascribe 149 includes an upper scribe portion 145 and a lower scribe portion 141. The lower scribe portion 141 defines a gap between bottom electrode 104-1 and bottom electrode 104-2. The upper scribe portion defines a gap between photoactive layer 106-1 and photoactive layer 106-2 and a gap between the top electrode 108-1 (or top conductor layer 107-1) and top electrode 108-2 (or top conductor layer 107-2). Structurally, the upper scribe portion 145 is generally wider than the lower scribe portion 141. An overall width of a megascribe may in most cases generally correspond to the width of the upper scribe portion. Referring to FIG. 1C, one end of megascribe 149 generally defines an edge of first cell 102-1 and the opposite end of the megascribe generally defines an adjacent edge of second cell 102-2. Although the PV cell layers adjacent the megascribe are shown as having vertical sidewall, they may take on a different angle or shape (curved, sloped, or the like). In some cases, the width of an upper scribe portion and/or a lower scribe portion may vary with depth (Z axis). In some embodiments, a minimum width of an upper scribe portion is greater than a maximum width of a lower scribe portion. In some preferred embodiments, the sidewalls do not form an overhang structure. For example, in some cases, a gap between the top electrodes should not be substantially smaller than the gap between the photoactive layers. In some embodiments, an upper scribe portion width (which may be measured as minimum, maximum, or an average) may be less than 500 μm, alternatively less than 400 μm, alternatively less than 300 μm, alternatively less than 250 μm, alternatively less than 200 μm, alternatively less than 175 μm, alternatively less than 150 μm, alternatively less than 125 μm, alternatively less than 100 μm, or alternatively less than 80 μm. In some embodiments, an upper scribe portion may have a width (which may be measured as minimum, maximum, or an average) in a range of 50 μm to 250 μm. Although smaller megascribe width dimensions may reduce inactive area, technology used for the deposition of insulating and series connection materials may limit how small the upper scribe portion should be. In some embodiments, the upper scribe portion width (minimum, maximum, or average) may be at least m, alternatively at least 40 μm, or alternatively at least 60 μm.

In some embodiments, an upper scribe portion or a lower scribe portion may, when viewed from above, not have perfectly straight edges. The edges when viewed from above may have a sculpted or some other non-linear appearance. In some cases, this may be due to the properties of the tool that is forming the scribe. For example, a laser etching tool may be used to form the megascribe. The laser beam may be a pulsed beam that is translated across the target area which may result in a non-linear megascribe edge.

As mentioned, the top electrodes may optionally include a composite conductor structure. Although the top set of metal lines 109-1 of the first PV cell are shown as not reaching the electrically conductive connector 131, in some embodiments, they may reach and make contact with the electrically conductive connector 131. In some embodiments, the top set of metal lines may be oriented approximately orthogonal to the megascribe, e.g., parallel to the X-axis in FIGS. 1A-1E.

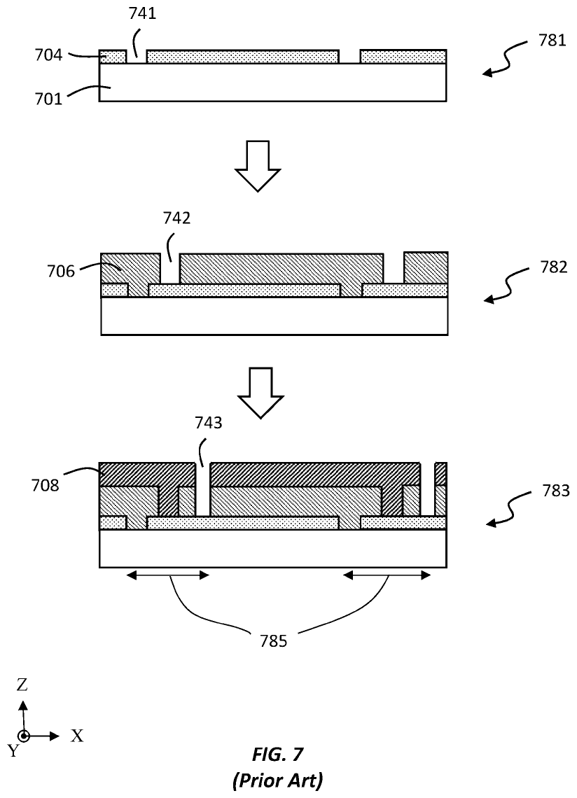

Referring to FIG. 1E, the inactive area of the PV module caused by making the interconnect may in some cases be substantially reduced relative to the traditional 3-scribe method described in FIG. 7. In some embodiments, the inactive area width may be as shown by width 185a, e.g., when the insulating materials 121, 123 and electrically conductive connector 131 are substantially opaque to target radiation. If the insulating materials are transparent, the inactive area width may be as shown by width 185b. If the insulating materials and electrically conductive connector can be made transparent, the inactive area width may be as shown by width 185c. In some embodiments, the inactive area width of the present PV module may be less than 500 μm, alternatively less than 400 μm, alternatively less than 300 μm, alternatively less than 250 μm, alternatively less than 200 μm, alternatively less than 175 μm, alternatively less than 150 μm, alternatively less than 125 μm, alternatively less than 100 μm, or alternatively less than 80 μm.

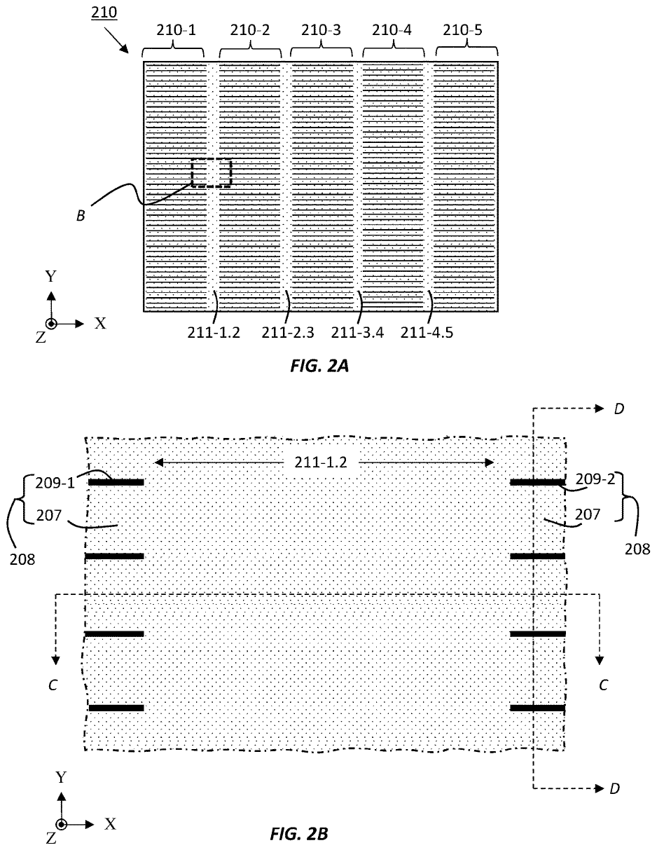

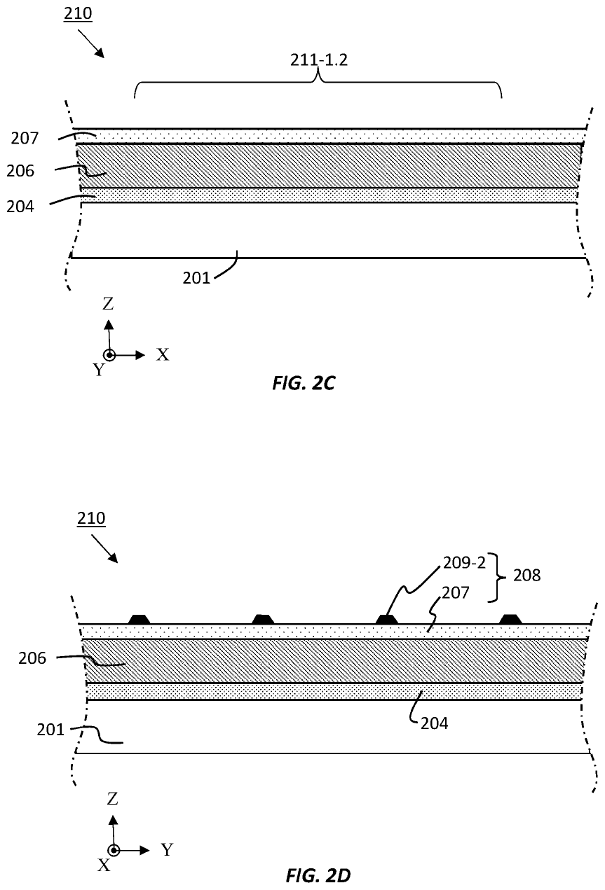

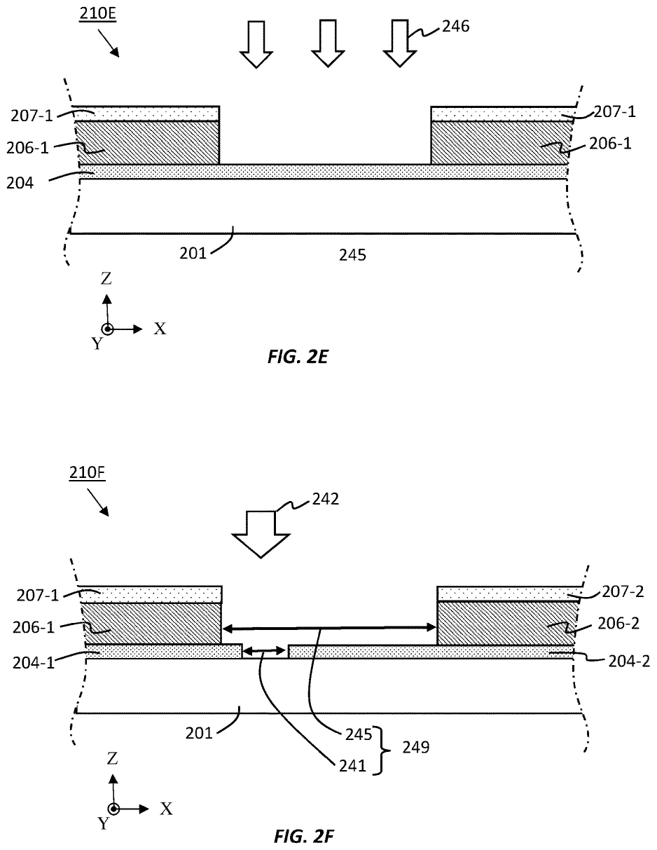

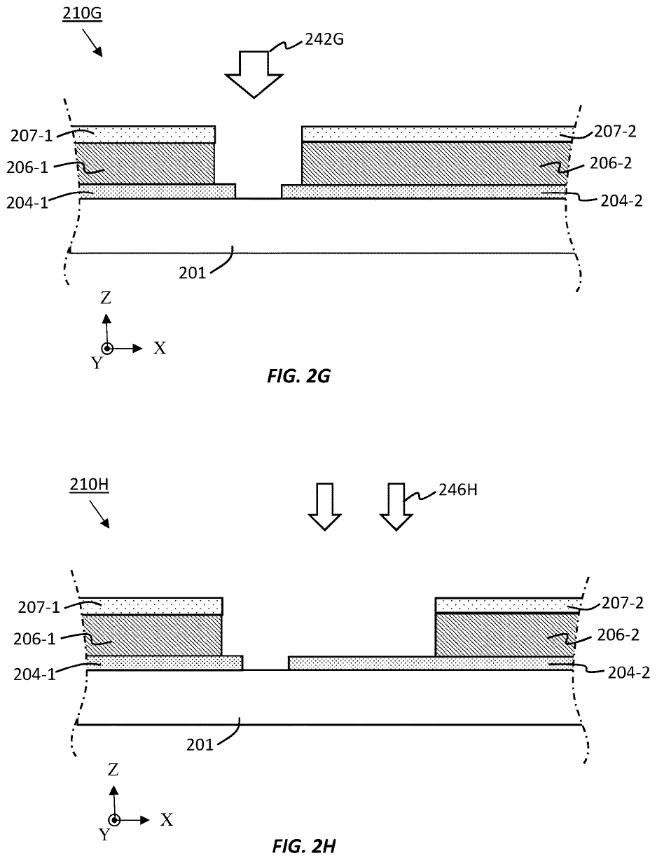

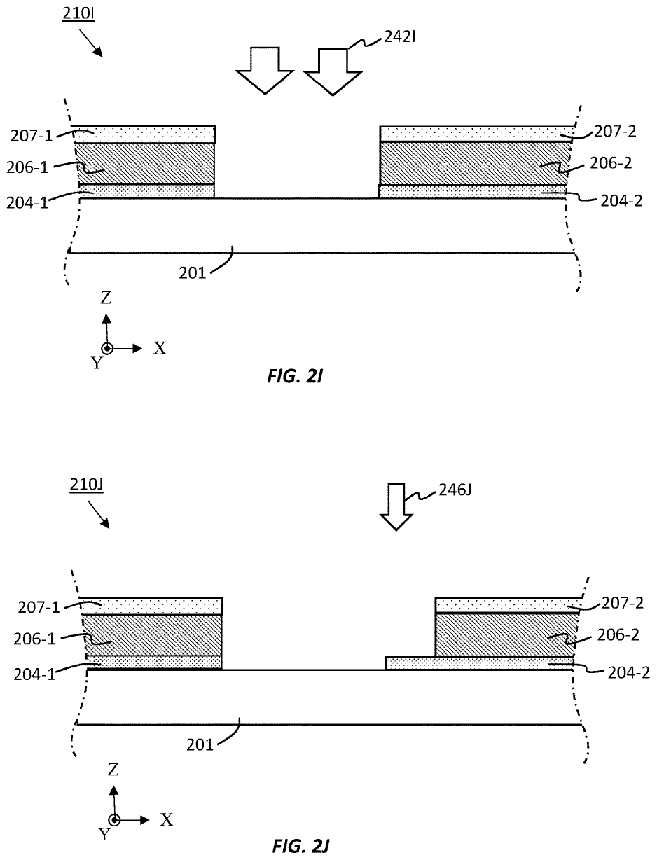

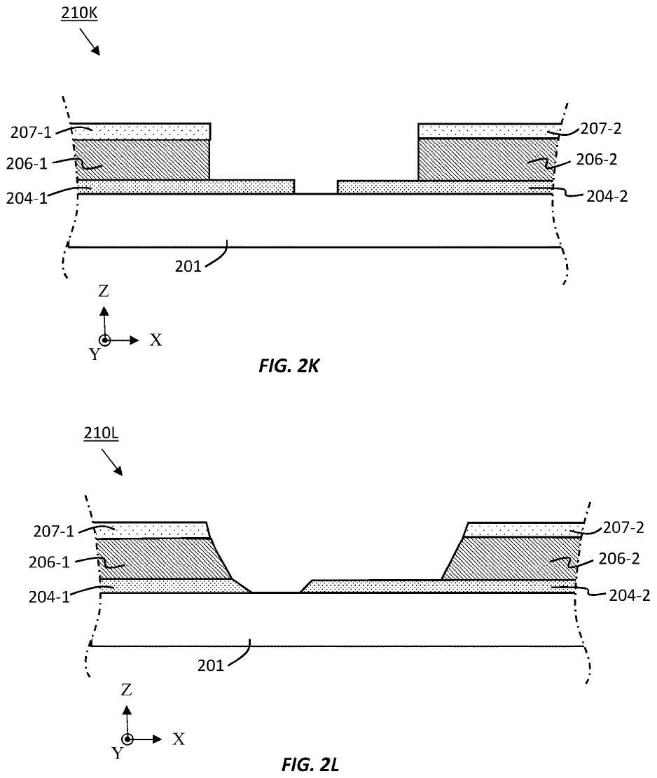

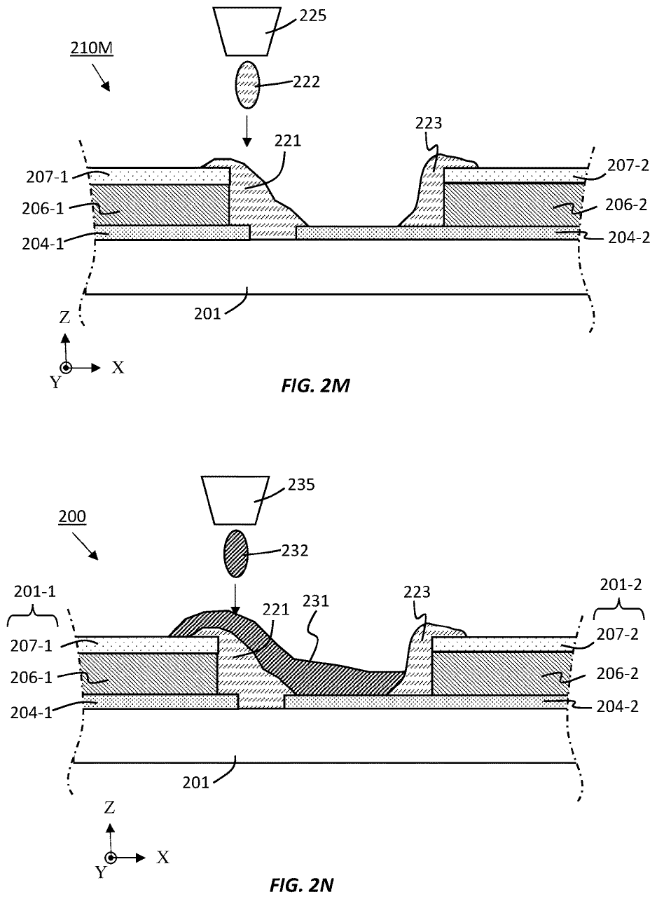

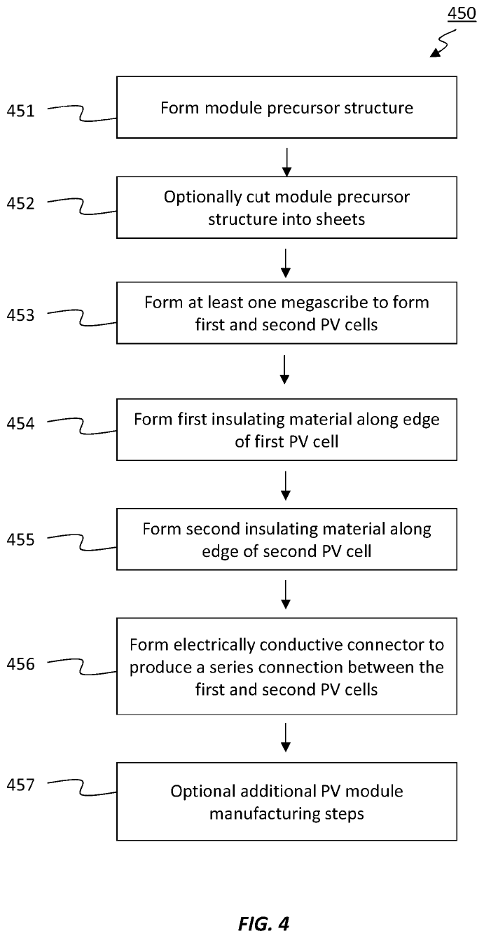

Referring briefly to FIG. 4, there is shown a flow diagram of some non-limiting steps for making a PV module according to some embodiments. A manufacturing process 450 may include a step 451 of forming a module precursor structure. FIGS. 2A-2D are various views of a perovskite-containing module precursor structure according to some embodiments. In particular, FIG. 2A is a top view of the module precursor structure 210, FIG. 2B is an enlarged top view of area B from FIG. 2A, FIG. 2C is a cross-sectional view along cutline C-C of FIG. 2B, and FIG. 2D is a cross-sectional view along cutline D-D of FIG. 2B.

In some embodiments, module precursor structure 210 may include patterned regions 210-1, 210-2, 210-3, 210-4, and 210-5 where the top electrode 208 includes a composite conductor of top conductor 207 and a set of top metal lines (209-1, 209-2, etc.). The gap between the top metal lines 209-1 of the first patterned region 210-1 and the top metal lines 209-2 of the second patterned region 210-2 may in some cases define a process target region 211-1.2. Similar gaps and process target regions may exist between other adjacent patterned regions, e.g., 211-2.3, 211-3.4, and 211-4.5.

The module precursor structure 210 includes a bottom electrode 204, a photoactive layer 206 disposed over the bottom electrode 204, and a top electrode 208 formed over the photoactive layer 206. As discussed with respect to FIGS. 1A-1E, the top electrode may in some embodiments be transparent. The top electrode may optionally be a transparent composite conductor having a transparent top conductor layer 207 provided over the photoactive layer 206 and sets of top metal lines (209-1, 209-2 . . . etc.) provided over the top conductor layer 207.

As discussed elsewhere, the module precursor structure 210 may in some cases be formed by roll-to-roll manufacturing processes. Alternatively, the module precursor structure may be formed as individual sheets. Referring again to FIG. 4, step 453 includes forming at least one megascribe to form first and second PV cells. If the module precursor structure is in the form of a roll or web, step 453 may be conducted directly on the module precursor structure as part of a web process. Alternatively, as shown in step 452, a roll or web-based module precursor structure may optionally be cut into sheets prior to step 453.

FIGS. 2E-2F are cross-sectional views at various stages of a non-limiting example of forming a megascribe in a module precursor structure according to some embodiments. In FIG. 2E, an intermediate structure 210E is formed where laser radiation 246 is used to remove material from the top electrode 208 (which in this area may include just top conducting layer 207) and the photoactive layer 206. In FIG. 2F, another intermediate structure 210F is formed where laser radiation 242 is used to remove material from the bottom electrode. Such processes may generally be referred to as laser etching. Together, laser radiation 246 and 242 may be used to form megascribe 249 having an upper scribe portion 245 and a lower scribe portion 241.

Laser radiation 246 may represent one beam having a desired width so that it does not require any lateral movement to form structure 210E. Alternatively, laser radiation 246 may be a narrower beam that is translated laterally (e.g., along the X-axis) to form the desired cut. Laser radiation 246 and structure 210E may represent the outcome of several laser etching events or steps rather than a single step. The terms “laser etching event” and “laser etching step” may be used interchangeably herein. The properties of laser radiation 246 may be selected so that it substantially removes the top electrode and photoactive layer, but does not substantially remove the bottom electrode, at least in the portion where a series connection is to be made. In some cases, the laser properties and materials for the module precursor structure (bottom electrode, photoactive layer, top electrode) may be co-selected to promote easy removal of the top electrode and photoactive layer but difficult removal of the bottom electrode. Some of the controllable properties of laser radiation 246 may include wavelength, beam width, beam shape, beam focus, power, pulse profile/width, position, movement, and the like.

As with laser radiation 246, laser radiation 242 may represent one beam having a desired width so that it does not require any lateral movement to form structure 210F. Alternatively, laser radiation 242 may be a narrower beam that is translated laterally (e.g., along the X-axis) to form the desired cut. Laser radiation 242 and structure 210F may represent the outcome of several laser etching steps rather than a single step. The properties of laser radiation 242 may be selected so that it substantially removes the bottom electrode, but does not deleteriously remove the underlying substrate. A small amount of substrate material may in some cases be removed. Some of the controllable properties of laser radiation 242 may include wavelength, beam width, beam shape, beam focus, power, pulse profile/width, position, movement, and the like.

Although FIGS. 2E and 2F show a particular sequential process, there are numerous options for forming a megascribe. For example, laser radiation 246 and 242 may be applied concurrently rather than sequentially, or even in the opposite order. FIGS. 2G-2H are cross-sectional views of another non-limiting example of forming a megascribe in a module precursor structure according to some embodiments. In FIG. 2G, laser radiation 242G is used to laser etch through the top electrode, the photoactive layer, and the bottom electrode to form intermediate structure 210G. In FIG. 2H, laser radiation 246H may be used to laser etch another portion of the top electrode and photoactive layer, but not the bottom electrode. In some cases, this may result in structure 210H that is similar to structure 210F in FIG. 2F, but made in a different way than shown in FIGS. 2E and 2F. In a manner similar to that discussed previously, considerations may be made regarding selection of the properties of the laser radiation and selection of materials for the module precursor structure. In some embodiments, laser radiation 242G and 246H may be applied concurrently rather than sequentially, or even in the opposite order.

FIGS. 2I-2J are cross-sectional views of another non-limiting example of forming a megascribe in a module precursor structure according to some embodiments. In FIG. 2I, laser radiation 2421 is used to laser etch through the top electrode, the photoactive layer, and the bottom electrode to form intermediate structure 210I. In FIG. 2J, laser radiation 246J may be used to laser etch another portion of the top electrode and photoactive layer, but not the bottom electrode, to form structure 210J. The structure is similar to that of 210F of FIG. 2F with respect to the upper scribe portion of the megascribe, but the width of the lower scribe portion is larger (although still less than the upper scribe portion). This embodiment demonstrates that the laser radiation used to form the lower scribe portion may in some cases also form some or even the majority of the upper scribe portion. In a manner similar to that discussed previously, considerations may be made regarding selection of the properties of the laser radiation and selection of materials for the module precursor structure. In some embodiments, laser radiation 2421 and 246J may be applied concurrently rather than sequentially, or even in the opposite order.

FIGS. 2K-2L are cross-sectional views of non-limiting examples of megascribes formed in a module precursor structure according to some embodiments. In FIG. 2K, structure 210K has a megascribe that is more symmetrical than that of FIG. 2F. In particular, the lower scribe portion is positioned approximately at the midpoint of the upper scribe portion. In FIG. 2L, structure 210L includes a megascribe that form PV cell sidewalls that are angled or even slightly curved. Either or both of structures 210K or 210L may be produced from a single beam of laser radiation, multiple beams of radiation, a single laser etching step, multiple laser etching steps. In a manner similar to that discussed previously, considerations may be made regarding selection of the properties of the laser radiation and selection of materials for the module precursor structure.

Although the above embodiments illustrate laser etching through electrodes or portions of electrodes not including metal lines, in some cases, the laser etching may be through a set of top metal lines and/or through a set of bottom metal lines. That is, a module precursor structure may not necessarily include a target processing region.

Any or all of the laser etching steps may optionally be performed under an inert atmosphere and/or in combination with an evacuation stream to carry away any potential debris. Although laser radiation is shown impinging the module precursor structure from the top (through the top electrode), in some embodiments, one or more laser radiation steps may be provided from the bottom (through the substrate). In some cases, laser radiation for both the top and bottom may be used. Laser radiation may in some cases impinge a top or bottom surface at an angle other than normal. The laser radiation may be in the form of a spot or line that moves across the substrate. For example, the laser source may be on a moveable arm or the beam may be coupled to redirection optics (mirrors, lenses or the like) to reposition the laser radiation impingement. Alternatively, or in combination, the module precursor structure may be moveable, e.g., on an X-Y stage. Depending on the power and other properties of the laser source, laser radiation may be applied to multiple areas concurrently across the module precursor structure. Multiple laser sources may be used concurrently in some cases.

The megascribe lasers may in part be housed in a processing station. Such processing station may further include sensors to ensure quality control, alignment, and proper production of the megascribe. In embodiments where the top electrode includes multiple sets of top metal lines, sensors of the processing station or the laser itself may detect the location of the top metal lines and the target process regions. Unlike prior art scribing methods such as in FIG. 7, the megascribe does not need to be carefully aligned to some pre-existing scribe made in a step that occurred in a separate station. Whether the megascribe uses one, two, or more laser etching steps, they may be done in a common processing station without intervening steps. This can significantly speed up manufacturing and reduce defects. In some cases, sensors may detect or quantify other laser etched scribes (megascribes, upper scribe portions, lower scribe portions, partially completed scribes, or the like) and that information may be used to align or otherwise direct the position of another laser etched scribe to be made.

The megascribe may be formed by directing a laser beam through a series of optics to achieve the desired focused spot size, thus creating the desired scribe width and depth. For example, the raw beam out of the laser may be passed through a collimating beam expander that may be set to a predetermined magnification in order to select the input beam size incident on the focusing optic. Selecting a smaller input beam size can result in a wider focused spot, and thus a wider scribe. The focusing optic (such as a plano-convex lens) may also be selected to have a specific focal length in order to achieve a target focused spot width. The focal window for these scribe processes is related to the Rayleigh length, which also improves with increasing focused spot size, resulting in a more robust and manufacturable process. In some cases a megascribe laser etch may utilize larger etch widths compared to laser etching used for traditional 3-scribe architectures (where the individual scribes may be less wide), therefore, the megascribe process can also benefit from a significantly improved process window.

The megascribe may be composed of one or more scribes of various widths; however, there are multiple considerations to make when choosing that composition. The width of the lower scribe portion may be determined in part by later process steps to be applied, e.g., forming the insulating materials or the electrically conductive connector. Thus, megascribe dimensions and other properties may be driven by the printer accuracy, repeatability, and wetting characteristics of the layers and printer inks. A wider scribe width may result in a wider process window, but this may result in a larger inactive area, so these factors should be considered in balance. Manufacturability may also be considered when selecting scribe width. A larger scribe width likely requires higher laser energy or power for a given source, and this could be limited by laser cost and the number of split beam paths used in a manufacturing tool.

Typical laser sources used for the traditional 3-scribe structure are still applicable for forming the megascribe. These include but are not limited to all permutations of nanosecond, picosecond and femtosecond pulse widths, with wavelengths in the UV, visible, NIR or IR ranges. For example, a pulsed green laser source (e.g., with a wavelength of 532 nm) may be used to selectively ablate the layers above a bottom transparent electrode without damaging the transparent bottom electrode, as it is absorbed strongly by the absorber layers, but not the transparent bottom electrode. The required pulse energy and pulse-to-pulse overlap will vary depending on the pulse width, pulse shape, beam incidence, spot size and shape, as well as the composition and thickness of the various layers of the module precursor structure. Under some permutations of these variables, laser fluences >80 mJ/cm² may be sufficient to create the upper portion of the scribe. However, lower fluences may also be possible.

To form the lower portion of the megascribe (that which ablates the bottom electrode and separates the area into two discrete cells), an IR source (e.g., at a wavelength of 1064 nm) may be desirable, as it may be absorbed significantly by a bottom transparent conducting layer. The required pulse energy and pulse-to-pulse overlap will vary depending on the pulse width, pulse shape, spot size and shape, and also the composition and thickness of the various layers, as well as the substrate itself. Under some permutations of these variables, laser fluences >40 mJ/cm² may be sufficient to create the lower portion of the scribe. However, lower fluences may also be possible.

Given the right parameters (pulse width, pulse energy, pulse overlap, spot size, etc.) any of these lasers may be a suitable source to form any portion or the whole of the megascribe.

Referring briefly to FIG. 4, after forming the megascribes, steps 454 and 455 include, respectively, forming a first insulating material along an edge of the first PV cell and forming a second insulating material along the adjacent edge of the second PV cell. FIG. 2M is a cross-sectional view of a non-limiting example of applying insulating materials according to some embodiments. The insulating material may be applied in the form of an insulator ink 222 which may be deposited from an ink applicator 225. In some cases, the ink applicator may be an inkjet device, but other applicators may be used such as a syringe, an extruder, laser-induced forward transfer (LIFT) printer, or some other appropriate device capable of patterned deposition. The insulator ink 222 may be applied to an edge of the first PV cell, which may optionally be dried, cured, or both to form intermediate structure 210M. Drying may be used to remove solvents and may include heating (oven, flashlamp, or the like) optionally at reduced pressure. Curing may initiate a chemical reaction that causes the insulator ink to become more solid, e.g., polymerization, cross-linking, or the like. In some cases, curing includes exposure to UV radiation, but may alternatively or in combination, include a heating step. In some cases, curing only needs time without a particular application of heat or UV. The solidified ink (by drying, curing, or just cooling) forms the first insulating material 221 and/or the second insulating material 223. The first insulating material 221 may in some cases be formed using the same insulator ink applicator 225 and insulator ink 222 as used for the second insulating material 223. In some cases, the same type of ink may be used but the first and second insulating materials are formed using separate applicators. In some cases, both the insulator ink and applicator used to form the first insulating material may different than those used form the second insulating material. At least a portion of the bottom electrode 204-2 of the second PV cell is not covered by either the first or second insulating materials.

The first and second insulating materials should not be electrically conductive. The first and second insulating materials may be electrically insulating, but may in some cases be semiconducting so long as it does not impede the functional performance of preventing undesired current flow. That is, with respect to desired device performance, the insulating materials can be considered functionally insulating. In some embodiments, the first and second insulating materials have an electrical resistance of at least 1 Ω·m, alternatively at least 105 Ω·m, or alternatively at least 10¹⁰ Ω·m. The insulating materials may be substantially transparent to visible light or alternatively may absorb some or most of visible light. In some cases, a transparent second insulating material may reduce the inactive area width, as mentioned with respect to FIG. 1E. In some cases, some or most of the visible light may be absorbed by the insulating material. This may be beneficial in quality control or alignment where sensors may be used to verify proper application of the insulating material.

The insulator ink 222 is generally in a fluid state when applied and may be a solution, a dispersion, or an emulsion. In some embodiments, the insulator ink may be solid or glassy at room temperature but can be heated to a fluid state and applied. Consideration should be made that forming the first and second insulating materials does not undermine the performance of the perovskite photovoltaic cell (e.g., from high temperature, solvents, additives, other materials, curing). While some interactions may occur at the PV cell sidewall, this is generally considered a non-active area (or at least a less-active areas) of the cell. The materials of the first and second insulating materials should generally not diffuse significantly into or otherwise damage the photoactive layer or electrode layer in the active portion of the cell.

In some embodiments, the insulating material may also act as a blocking layer to reduce or prevent the ingress of unwanted ions or other compounds into or out of the PV cell, in particular, the photoactive layer that includes the perovskite absorber. Some examples of potentially problematic ion diffusion may include iodide from the perovskite and metal ions such as silver ion from the electrically conductive connector. Utilizing the insulating material as a blocking layer, therefore, enables more manufacturable and widely available conductive inks to be used in subsequent steps.

Forming the insulating materials may optionally be performed under an inert atmosphere and/or in combination with an evacuation stream to carry away possible solvents or the like that may be used in the insulator ink. An insulator ink applicator may be provided on a moveable arm that translates across the substrate to enable patterned deposition. Alternatively, or in combination, the substrate may be moveable, e.g., on an X-Y stage. In some cases, insulator inks applied to multiple areas concurrently across the structure.

In some embodiments, the overall width of the first insulating material or second insulating material, e.g., as measured parallel to an X-axis of FIG. 2M, may be in a range of 20 μm to 300 μm, alternatively 50 μm to 200 μm. In some cases, the overall height or thickness of the first or second insulating material, e.g., as measured parallel to a z-axis of FIG. 2M, may be at least as high as the PV cell layers. If the edge of a PV cell has a slope, the thickness of the insulating material may actually be even less than the thickness of the PV cell stack. In some cases, the thickness or overall height of the first or second insulating material may be at least 50 nm, alternatively at least 100 nm, alternatively at least 200 nm, alternatively at least 500 nm, alternatively at least 1000 nm. In some cases, the thickness or overall height of the first or second insulating material may be less than 3000 nm, alternatively less than 2000 nm.

The insulator ink applicator may in part be housed in a processing station, optionally along with some or all of the megascribe laser equipment. Such processing station may further include sensors to ensure quality control, alignment, and proper production of the first and second insulating materials. In some cases, sensors may detect or quantify first or second insulating materials and that information may be used to align or otherwise direct the position of another insulator ink application step.

Some non-limiting examples of insulator inks and insulating materials may include polymers, ceramics, and graphitic materials. Some non-limiting examples of polymeric materials may include acrylics, epoxies, urethanes, silicones, polyamines, or polyimides. Some non-limiting examples of ceramic materials may include aluminum oxide, silicon dioxide, magnesium oxide, and titanium oxide. Some non-limiting examples of graphitic materials may include graphene oxide and carbon nitride.

Although described as formed from patterned deposition of a fluid material, which has high-speed manufacturing benefits, the first and second insulating materials may in some cases be formed using alternative methods such as vapor deposition of an appropriately insulating material, e.g., through a shadow mask. Alternatively, an insulating precursor material (a type of insulator ink) may be itself photo-patternable so that it may be generally coated, exposed with desired pattern, and chemically developed, to form the patterned first and second insulating materials.

Referring briefly to FIG. 4, after forming at least the first insulating material, and preferably after forming both the first and second insulating materials, step 456 includes forming an electrically conductive connector to produce a series connection between the first and second PV cells. FIG. 2N is a cross-sectional view of a non-limiting example of applying an electrically conductive connector according to some embodiments. The electrically conductive connector may be formed from conductive ink 232 which may be deposited from a conductive ink applicator 235. In some cases, the ink applicator may be an inkjet device, but other applicators may be used such as a syringe, an extruder, or some other appropriate device capable of patterned deposition. The conductive ink 232 may be applied over the first insulating material and onto the top electrode 207-1 of the first PV cell and also onto a portion of bottom electrode 204-2 of the second PV-cell. If application of the conductive ink can be made accurate enough, it can optionally be applied before the second insulating material is formed. Preferably, the conductive ink is applied after forming the second insulating material to ensure no unwanted contact of the conductive ink is made with the photoactive layer 206-2 or top electrode 207-2 of the second PV cell. Although not shown in FIG. 2N, the first PV cell top electrode may further include metal lines 209-1 and the second PV cell top electrode may further include metal lines 209-2, as shown, e.g., for a corresponding module precursor structure 210 in FIGS. 2A-2D. The conductive ink 232 may be dried, cured, sintered, or some combination to form PV module 200. Drying may be used to remove solvents and may include heating (e.g., in an oven, contact with a hot gas (air or inert), exposure to infrared radiation, use of a flashlamp, or the like) optionally at reduced pressure. Curing may initiate a chemical reaction that causes the conductive ink to become more solid, e.g., polymerization, cross-linking, or the like. In some cases, curing includes exposure to UV radiation, but may alternatively or in combination, include a heating step, e.g., in an oven, contact with a hot gas (air or inert), or exposure to infrared radiation. In many cases, the deposited conductive ink may include a sintering step which is also a type of heating step that may improve the conductivity of the electrically conductive connector material, particularly those formed from metal-containing conductive inks. In some cases, a flashlamp, a laser, an infrared source, or some other photonic device may be used to induce sintering (or drying or curing).

The electrically conductive connector may in some cases have a conductivity of at least 100 S/m, alternatively at least 10⁴ S/m. In some embodiments, the electrically conductive connector may make an ohmic contact with the top electrode of the first PV cell and with the bottom electrode of the second PV cell. In some embodiments, the electrically conductive connector may be substantially opaque and/or reflective. This may be beneficial in quality control or alignment where sensors may be used to verify proper application of the electrically conductive connector. In some case, the electrically conductive connector may include silver. In some cases, the electrically conductive connector may include copper. In some cases, silver may have certain advantages such as higher conductivity and less-harsh sintering/drying conditions. In some cases, copper may have certain advantages such as lower cost or less harmful ion migration if the insulating materials do not have sufficient silver-ion blocking properties.

In some embodiments, the electrically conductive connector may be transparent or partially transparent, e.g., made from some metal nanowire, carbon nanotube, or graphene ink formulations). In combination with transparent insulating materials, this may reduce the inactive area width as described in FIG. 1E.

The conductive ink is generally in a fluid state when applied and may be a solution, a dispersion, or an emulsion. Consideration should be made that forming the electrically conductive connector does not undermine the performance of the perovskite photovoltaic cell (from high temperature, solvents, additives, other materials, sintering). The electrically insulating materials preferably block significant diffusion of conductive ink components. While some interactions may occur at or through the top electrode near the edge of the second PV cell, this is generally considered a non-active area (or at least a less-active areas) of the cell.

Forming the electrically conductive connector may optionally be performed under an inert atmosphere and/or in combination with an evacuation stream to carry away possible solvents or the like that may be used in the conductive ink. A conductive ink applicator may be provided on a moveable arm that translates across the substrate to enable patterned deposition. Alternatively, or in combination, the substrate may be moveable, e.g., on an X-Y stage. In some cases, conductive inks applied to multiple areas concurrently across the structure.

In some embodiments, the overall width of the electrically conductive connector, e.g., as measured parallel to an X-axis of FIG. 2N, may be in a range of 30 μm to 500 μm, alternatively 100 μm to 300 μm. This width depends in part upon the dimensions of the megascribe and the insulating materials. The thickness of the electrically conductive layer may depend in part on the material conductivity.

The conductive ink applicator may in part be housed in a processing station, optionally along with some or all of the megascribe laser equipment, and/or the insulator ink equipment. Such processing station may further include sensors to ensure quality control, alignment, and proper production of the electrically conductive connector. In some cases, sensors may detect or quantify electrically conductive connectors and that information may be used to align or otherwise direct the position of another conductive ink application step.

Conductive inks are discussed elsewhere herein and any of these may be used for making the electrically conductive connectors. In some embodiments, the conductive ink may include silver. In some embodiments, the conductive ink may include copper. Each may have their own set of advantages as discussed with respect to the electrically conductive connector.

Although described as formed from patterned deposition of a fluid material, which has high-speed manufacturing benefits, the electrically conductive connector may in some cases be formed using alternative methods such as vapor deposition of an appropriately conducting material, e.g., through a shadow mask.

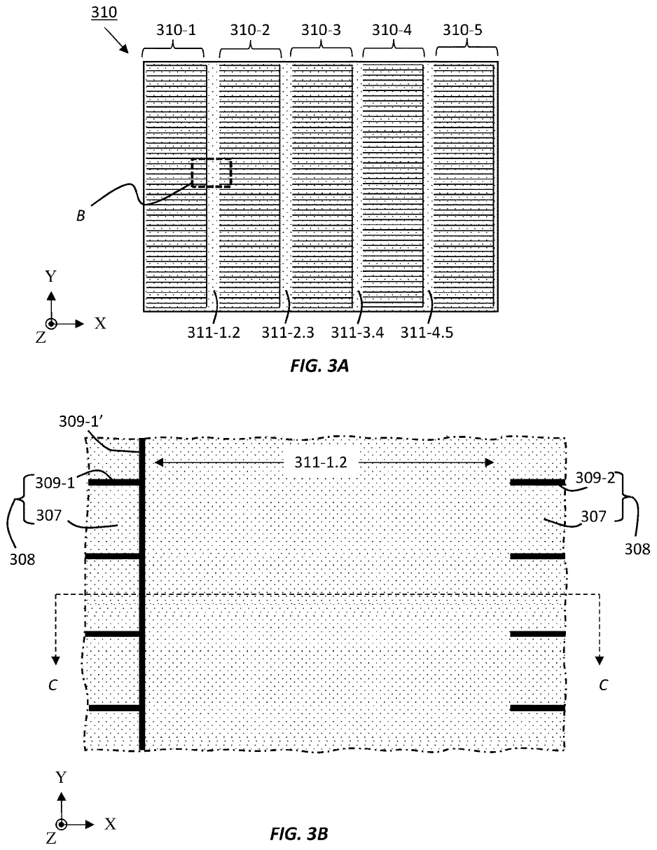

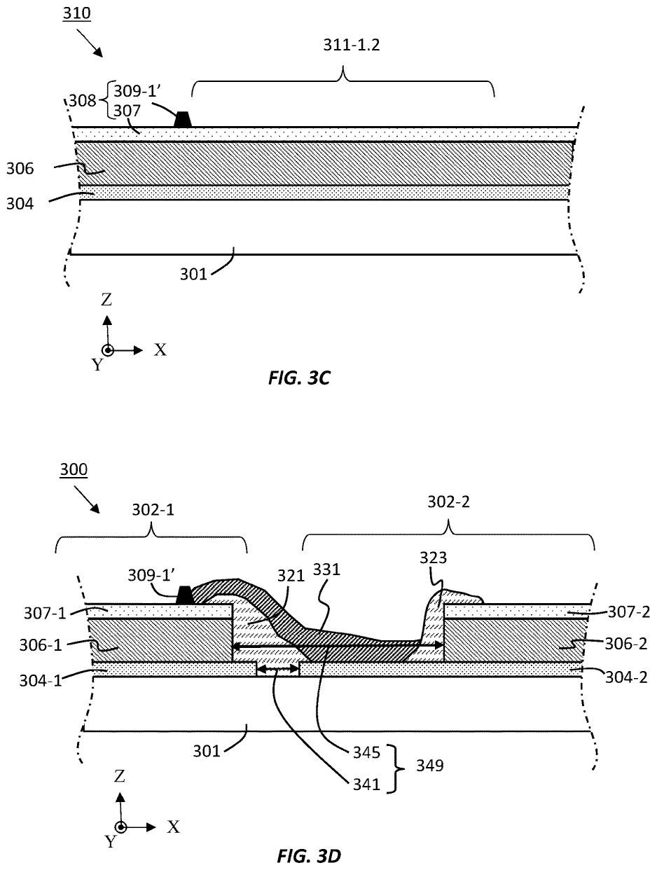

FIGS. 3A-3C are various views of another non-limiting example of a perovskite-containing module precursor structure according to some embodiments. In particular, FIG. 3A is a top view of the module precursor structure 310, FIG. 3B is an enlarged top view of area B from FIG. 3A, and FIG. 3C is a cross-sectional view along cutline C-C of FIG. 3B. Module precursor structure 310 is similar to module precursor structure 210 of FIGS. 2A-2C, but includes an alternative top electrode structure as discussed below.

In some embodiments, module precursor structure 310 may include patterned regions 310-1, 310-2, 310-3, 310-4, and 310-5 where the top electrode 308 includes a composite conductor 308 of top conductor 307 and a set of top metal lines 309-1, 309-2, etc. Each patterned region further includes an edge metal line positioned at least at one edge of the intended PV cell. For example, first patterned region 310-1 includes, in addition to top metal lines 309-1, edge metal line 309-1′ that runs approximately orthogonal to the other top metal lines and approximately parallel to the Y-axis in these figures. The space or gap between the top metal lines 309-1/309-1′ of the first patterned region 310-1 and the top metal lines 309-2 of the second patterned region 310-2 may define a process target region 311-1.2. Similar gaps and process target regions may exist between other adjacent patterned regions, e.g., 311-2.3, 311-3.4, and 311-4.5.

The module precursor 310 includes a bottom electrode 304, a photoactive layer 306 disposed over the bottom electrode 304, and a top electrode 308 formed over the photoactive layer 306. As discussed with respect to FIGS. 1A-1E, the top electrode may in some embodiments be transparent. The top electrode may optionally be a transparent composite conductor having a transparent top conductor layer 307 provided over the photoactive layer 306 and sets of top metal lines (309-1, 309-1′, 309-2 . . . etc.) provided over the top conductor layer 307.

Upon processing, e.g., as described with respect to FIG. 4 and FIGS. 2A-2N, a PV module 300 may be formed as shown in FIG. 3D. Perovskite PV module 300 includes a substrate 301, a first PV cell 302-1 including bottom electrode 304-1, photoactive layer 306-1, and top electrode 307-1/309-1′, and a second PV cell 302-2 including bottom electrode 304-2, photoactive layer 306-2, and top electrode 307-2. Although not shown in FIG. 3D, the first PV cell top electrode may further include metal lines 309-1 and the second PV cell top electrode may further include metal lines 309-2, as shown, e.g., for a corresponding module precursor structure 310 in FIGS. 3A-2B. The first and second PV cells are separated by a megascribe 349 extending along a first dimension that may be generally parallel to the Y axis. Megascribe 349 includes an upper scribe portion 345 and a lower scribe portion 341. A first insulating material 321 is provided along the edge of the first PV cell 302-1. A second insulating material 323 is provided along the edge of the second PV cell 302-2. At least a portion of bottom electrode 304-2 of the second PV cell is not covered by either the first or second insulating layers. An electrically conductive connector 331 is provided that extends over the first insulating material and is in electrical contact with a portion of the top electrode 307-1/309-1′ of the first PV cell and with a portion of the bottom electrode 304-2 of the second PV cell to form a series connection between the first and second PV cells.

In FIG. 3D, the electrically conductive connector may make contact directly with the edge metal line 309-1′. This may in some embodiments reduce overall resistance of the system. The edge metal line 309-1′ may optionally serve as a dam during deposition of inks used to form the first insulating material or the electrically conductive connector.

As discussed elsewhere, the top electrode may include a composite conductor having a transparent conductive layer such as a conductive oxide and a set of top metal lines. The metal lines can substantially lower the resistance of the top electrode, but the improvement depends in part on the cross-sectional area of the metal lines. At equal width, tall metal lines are better conductors than short metal lines. Although the laser etching steps used to form the megascribes can be designed to etch through metal lines, it can sometimes be difficult to etch through tall metal lines. In embodiments where the top electrode includes metal lines only outside of the target process regions (as shown for example in FIGS. 1A-1E, 2A-2D, and 3A-3C), no laser etching of the top set of metal lines is required. As a result, the set of top metal lines, including any edge metal lines, may optionally be quite tall relative to other layers. Further, taller metal lines may in some cases allow the use of conductive inks that are less harmful to the perovskite PV module. For example, some copper-based conductive inks may interact less with the perovskite cells than silver-based inks. Although less conductive than silver, this can be compensated for by using taller copper lines. Also, sintering conditions for some metal inks to achieve ideal conductivity may be too harsh on the underlying perovskite PV cell layers. Applying more compatible sintering conditions may result in a less conductive metal line but it can be compensated for by making the metal line taller.

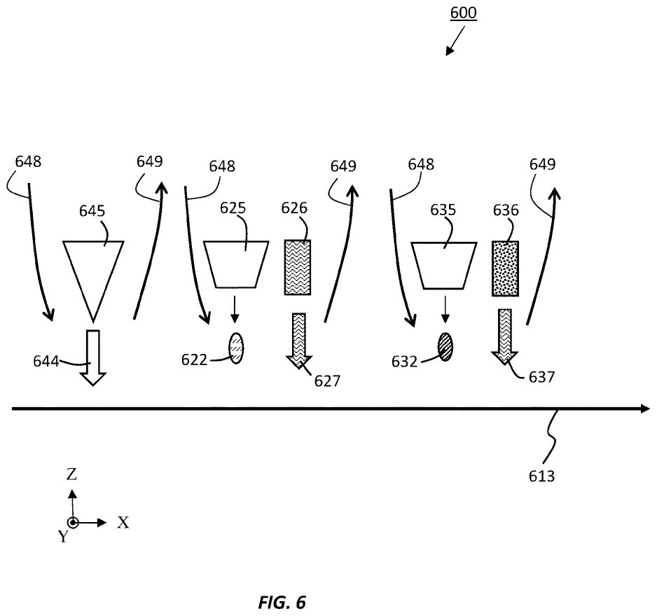

Referring to FIG. 6 there is shown a cross-sectional schematic of a non-limiting example of an interconnect processing station according to some embodiments. Processing station 600 does not explicitly show a module precursor structure, but indicates a general plane and direction 613 that it may move along relative to the various components of the processing station. That is, direction 613 indicates relative motion and either the module precursor structure or the processing tools (or both) may move relative to each other. Processing station 600 may include a megascribe laser tool 645 for producing and controlling laser radiation 644 for use in forming upper and lower scribe portions. Laser tool 645 may optionally include multiple individually adjustable lasers and its position may be adjustable in any direction (X, Y, and/or Z). In some cases, a flow of inert gas 648 such as nitrogen may be associated with the laser tool 645 along with an optional exhaust 649.

Processing station 600 may include an insulator ink applicator tool 625 for dispensing/patterning insulating ink 622 for forming the first and second insulating materials. Insulator ink applicator tool 625 may optionally include multiple individually controllable ink applicators and its position may be adjustable in any direction (X, Y, and/or Z). In some cases, the insulator ink applicator tool 625 may include an inkjet device. A curing tool 626 may optionally be provided for applying curing conditions 627 (e.g., UV radiation, heat, or the like) to the deposited insulator ink. The curing tool 626 may in some cases follow closely behind the insulator ink applicator tool 625. The curing tool may optionally include multiple individually controllable curing devices and its position may be adjustable in any direction (X, Y, and/or Z). In some cases, the curing tool 626 may include a UV curing device. In some cases, a flow of inert gas 648 such as nitrogen may be associated with the insulator ink applicator tool and/or the curing tool along with an optional exhaust 649.

Processing station 600 may include a conductive ink applicator tool 635 for dispensing/patterning conductive ink 632 for forming the electrically conductive connector. Conductive ink applicator tool 635 may optionally include multiple individually controllable ink applicators and its position may be adjustable in any direction (X, Y, and/or Z). In some cases, the conductive ink applicator tool 635 may include an inkjet device. A sintering tool 636 may be provided for applying sintering conditions 637 to the deposited conductive ink. The sintering tool 636 may in some cases follow closely behind the conductive ink applicator tool 635. The sintering tool may optionally include multiple individually controllable sintering devices and its position may be adjustable in any direction (X, Y, and/or Z). In some cases, the sintering tool 636 may include a flashlamp or a laser. In some cases, a flow of inert gas 648 such as nitrogen may be associated with the conductive ink applicator tool and/or the sintering tool along with an optional exhaust 649.

Although not shown, the interconnect processing station may include sensors for safety and quality control, and electronic communication between the tools and a computer control system.

Including each of a megascribe laser tool, an insulating material applicator tool, and a conductive connector applicator tool in an interconnect processing station as show in FIG. 6 allows efficient sequential performance of the described interconnect manufacturing steps at a single processing station, and further advantageously enables concurrent performance of the described manufacturing steps at different locations of a single module precursor structure or of multiple module precursor structures in a continuous process. More particularly, forming an additional megascribe which defines additional photovoltaic cells in a module precursor structure at the common interconnect processing station may be performed concurrently with forming of the first and second insulating materials along the edges of the first and second photovoltaic cells. Additionally or alternatively, forming an additional insulating material along an edge of an additional photovoltaic cell in a module precursor structure at the common interconnect processing station may be performed concurrently with forming of the electrically conductive connector making a series connection between the first and second photovoltaic cells.

Referring again to FIG. 4, step 457 may include optional additional PV module manufacturing steps after the series connections have been made. Some non-limiting examples of additional manufacturing steps may include application of an adhesive or encapsulation layer over the PV cells, bonding a superstrate over the adhesive or encapsulation layer, cutting operations, electrical bonding, and inspection.

### Perovskite PV Structure

FIG. 5 is a cross-sectional view of a non-limiting example of a perovskite PV structure according to some embodiments. The PV structure may represent a PV cell or a module precursor structure. The photovoltaic structure 500 may include a substrate 501, which may be transparent, and which may in some cases be flexible. A bottom electrode 504 may be provided over the substrate. Bottom electrode may be transparent (e.g., it may include a conductive metal oxide or a transparent composite conductor) or opaque (e.g., include a metal layer or a metal/conductive metal oxide bilayer such as where the conductive metal oxide layer is disposed over the metal layer).

A first carrier transport layer 563 may be provided overlaying the bottom electrode. In some embodiments, it is useful that carrier transport layer(s) overlaying the bottom electrode do not physically contact a metallic electrode due to possible ion migration. A perovskite absorbing layer 564 (sometimes referred to herein simply as a perovskite layer) may be provided overlaying the first carrier transport layer. A second carrier transport layer 565 may be provided overlaying the perovskite absorbing layer. Layers 563, 564, and 565 may be collectively referred to herein as a photoactive layer 506

A top electrode 508 may be provided overlaying the second carrier transport layer. At least one of the top and bottom electrodes are transparent. In some embodiments, top electrode 508 is opaque and may include a metal layer or a metal/conductive metal oxide bilayer such as where the metal layer is disposed over the conductive metal oxide layer. In some preferred embodiments, at least the top electrode 508 is transparent. The top electrode may be a transparent composite conductor including top conducting layer 507 and a top set of conductive metal lines 509 provided in contact with the top conducting layer. In some preferred embodiments, top metal lines 509 are generally not in direct contact with the second carrier transport layer 565.

In operation, positive and negative charges (holes and electrons) are produced in the perovskite absorbing layer 564 in response to absorption of appropriate radiation. The first and second carrier transport layers (563, 565) receive these separated charges and transfer them to the respective bottom and top electrodes (504, 508). The bottom and top electrodes may be in electrical contact with an electrical device (not shown in FIG. 5) where the collected charges serve to power the device, or alternatively charge it in the case where the electrical device is an energy storage battery of some sort.

In some embodiments, the first carrier transport layer may include a hole transporting material and the bottom electrode may act as an anode in the photovoltaic structure. In such embodiments, the second carrier transport layer may include an electron transporting material and the top electrode may act as a cathode in the photovoltaic structure. Such an arrangement of layers may for convenience be referred to as a PIN structure.

In some alternative embodiments, the first carrier transport layer may include an electron transporting material and the bottom electrode may act as cathode in the photovoltaic structure. In such embodiments, the second carrier transport layer may include a hole transporting material and the top electrode may act as an anode in the photovoltaic structure. Such an arrangement of layers may for convenience be referred to as a NIP structure.

The layers between the bottom and top electrodes shown in FIG. 5 may sometimes be referred to herein as photovoltaic “active layers”. Although not illustrated in FIG. 5, in some embodiments, one or more interfacial layers may optionally be provided between any adjacent active layers, between an active layer and an electrode, over the top electrode or under the bottom electrode. Herein the term “interfacial layer” is used broadly, with the purpose, e.g., of altering one or more properties of the interface between two layers such as changing the work function, increasing the barrier properties to mobile ions, passivating defects in a neighboring layer, or altering the band gap. In some cases, an interfacial layer may more specifically act as a barrier to diffusion of water, solvents, molecules, ions (e.g., metal ions and/or halide ions). In some embodiments an interfacial layer may passivate, deactivate or otherwise ameliorate unwanted trap states or carrier transport barriers at layer interfaces or even grain boundaries. An interfacial layer may in some embodiments include a generally electrically insulating metal oxide (e.g., aluminum oxide, titanium dioxide, or the like) that is sufficiently thin so as not to seriously impede the transport of charge between layers. In some embodiments, an interfacial layer may be less than 6 nm, alternatively less than 2 nm. In some cases, an interfacial layer may be a few monolayers thick, alternatively a single monolayer thick. In some cases, an interfacial layer may be a continuous layer or film, but in other cases may be discontinuous. In some embodiments, an interfacial layer may be applied by an inline tool compatible with roll-to-roll manufacturing. In some cases, an interfacial layer may be applied by spatial ALD (SALD), a reduced pressure metal oxide deposition tool, or coating (or other contact) with a solution, liquid, gas, or aerosol that includes an interfacial material. Additionally, anywhere the phrase “interfacial layer” or similar concepts appear herein, they may be replaced by “interfacial treatment”. In some cases, an interfacial treatment may not result in deposition of an interfacial layer but may instead treat a layer at its surface or even internally to provide the desired treatment result.

In some embodiments, the materials and methods used for forming one or more layers of the photovoltaic structure are compatible with high-speed manufacturing. In some cases, one or more layers may be formed using roll-to-roll processes. In some embodiments, one or more manufacturing steps may instead use batch deposition methods or a series of substrates in a “cut sheet” format, e.g., with each mounted in a frame.

### Substrate

The substrate is generally electrically insulating and may be formed from any suitable material(s). For use with transparent bottom electrodes, the substrate may be formed from any suitable transparent material(s), such as a glass, a polymer (plastic), or a combination of different materials. The substrate may in some cases be rigid, but in preferred embodiments, the substrate is flexible. Some non-limiting examples of transparent substrates may include thin flexible glass such as Corning® Willow® Glass, a polyethylene terephthalate (PET) (which may optionally be a heat-stabilized PET), a polyethylene naphthalate (PEN), a polycarbonate (PC), a polysulfone (PS), a polyether sulfone (PES), a polyamide, p-nitrophenylbutyrate (PNB), a polyetherketone (PEEK), a polyetherimide (PEI), a polyarylate (PAR), a polyvinyl acetate, a polyimide, a cyclic olefin polymer (COP), a cellulose triacetate (TAC), a polyacrylate, or an epoxide. For some applications, some particularly useful transparent substrates include thin flexible glass, PET and heat-stabilized PET. The substrate may optionally include multiple materials or have a multilayer structure. The substrate may include a surface treatment to modify the surface energy for improved coating quality and/or adhesion of subsequent layers. Some non-limiting examples of surface treatments include corona discharge, ozone (created, for example, with ultraviolet radiation), and plasma. Surface treatment devices may operate in ambient air, conditioned air (where temperature and relative humidity are controlled), oxygen, or inert gas such as nitrogen or argon. In some embodiments, a surface-modifying treatment may involve a wet chemical treatment or even an additional surface layer deposited by a wet- or dry-coating method. In some cases, a surface layer may be referred to as a primer layer. In some cases, the substrate may act as a water vapor or oxygen barrier, e.g., through choice of substrate material or by addition of one or more barrier layers.

Note that by “flexible” it is generally meant that the material can undergo some shape changes at least in one dimension in response to some force or stress without significant damage. In some cases, flexibility of a substrate or material may be measured by its bend radius, which is the minimum radius that it can be bent without functionally damaging it. In some embodiments, a flexible support may have a bend radius of less than 100 cm, alternatively less than 50 cm, 20 cm, 10 cm, 5 cm, 4 cm, 3 cm, 2 cm, or 1 cm. In some preferred embodiments, a flexible substrate may have a bend radius of less than 10 cm.

There are no particular limitations on the thickness of the substrate if flexibility is not desired, so long as it remains sufficiently transparent when required. In some preferred embodiments, a flexible substrate is suitable for roll-to-roll manufacturing and may have a thickness of less than about 350 μm if it is flexible glass (e.g., a thickness in a range of 50 to 350 μm), or alternatively less than about 200 μm if it is a flexible plastic (e.g., a thickness in a range of 20 to 250 μm).

### First and Second Carrier Transport Layers

As mentioned, one carrier transport layer includes a hole transporting material, and the other carrier transport layer includes an electron transporting material. A carrier transport material that includes a hole transporting material may be referred to as a hole transport layer. In addition to transporting holes, a hole transporting material may also effectively block the transport of electrons. A carrier transport material that includes an electron transporting material may be referred to as an electron transport layer. In addition to transporting electrons, an electron transporting material may also effectively block the transport of holes. In some embodiments, a carrier transport layer may include multiple layers of materials. A non-limiting example of a multilayer charge transport layer may include embodiments where one sublayer is especially for transporting the desired charge and another sublayer especially for blocking the opposite charge. In some cases, a blocking sublayer may be adjacent to the perovskite blocking layer. The thickness of a carrier transport layer depends in part on the properties of the overall photovoltaic stack, but in some embodiments, may have an average thickness in a range of 10's to 100's of nanometers.

Some non-limiting examples of hole-transporting materials may include a poly(triaryl amine) (e.g., poly[bis(4-phenyl)(2,4,6-trimethylphenyl)amine]), a poly-(N-vinyl carbazole), PEDOT complex, a poly(3-hexylthiophene), spiro-MeOTAD (also known as N²,N²,N²′,N²′,N⁷,N⁷,N⁷,NT-octakis(4-methoxyphenyl)-9,9′-spirobi[9H-fluorene]-2,2′,7,7′-tetramine), poly-TPD, EH44, certain metal oxides (e.g. nickel oxide, molybdenum oxide, and vanadium oxide, any of which may optionally be doped), copper thiocyanate and copper iodide, and certain self-assembled monolayers (e.g. 2-(9H-Carbazol-9-yl)ethyl]phosphonic acid) Some non-limiting examples of electron-transporting materials may include fullerenes, (e.g., phenyl-C61-butyric acid methyl ester (PCBM) and fullerene-C60), bathocuproine (BCP), TPBI, PFN, PC₇₁BM, ICBA, graphene, reduced graphene oxide, certain metal oxides (e.g., tin oxide, zinc oxide, cerium oxide, and TiO₂, any of which may optionally be doped).

Depending in part upon the particular material, a carrier transport layer may in some cases be deposited by a dry deposition process. Some non-limiting examples of dry processes may include sputtering, thermal evaporation, physical vapor deposition, chemical vapor deposition, atomic layer deposition, e-beam deposition, or some other process that may in some cases operate under reduced pressure. In some cases, dry deposition may be performed inline in a roll-to-roll system, e.g., by using spatial ALD (SALD) or a reduced pressure material deposition (RPMD) tool. Such RPMD tools operate at pressures above normal vacuum deposition systems, e.g., in a range of 0.01 mBar to 200 mBar. In some embodiments, a carrier transport layer may be deposited from an aerosol of nanoparticles. Some non-limiting examples of aerosol-based deposition are described in U.S. Ser. No. 10/092,926, which is incorporated by reference herein in its entirety for all purposes. In some cases, aerosol deposition has been found to be less damaging to underlying device layers.

In some embodiments, a carrier transport layer may be deposited by a coating process that does not require reduced pressure. Some non-limiting examples of coating processes may include gravure, slot die, spray, dip coat, inkjet, flexographic, rod, or blade coating methods. In some cases, a coating process may be followed by a thermal treatment to drive off solvent, anneal the carrier transport material, or the like.

In some embodiments, a carrier transport layer may be deposited by transfer of the carrier transport material from a donor sheet, e.g., by application of heat or some other stimulus to release it from the donor sheet with adherent transfer to the appropriate device layer or substrate.

In some cases, the deposition method is suitable for high-speed manufacturing. In some embodiments, the deposition of one or more carrier transport layers may be performed using a roll-to-roll manufacturing process.

### Perovskite Absorbing Layer

Perovskite materials and methods for forming perovskite absorbing layers may be as described in U.S. Pat. Nos. 11,108,007, 11,342,130, U.S. Application No. 2020/0377532, and U.S. Application Publication No. 2022/0238807, the entire contents of which are incorporated herein by reference. In some embodiments, a perovskite absorbing layer may be coated from a fluid mixture, which may be referred to as a perovskite solution. Any coating method suitable for coating a fluid mixture may be used including, but not limited to, gravure, slot die, spray, dip coat, inkjet, flexographic, rod, or blade coating methods. In some cases, the perovskite deposition method is suitable for high-speed manufacturing. In some embodiments, a perovskite absorbing layer may be performed using a roll-to-roll manufacturing process.

The term “perovskite solution” refers to a solution or colloidal suspension that can be used to generate a continuous layer of organic-inorganic hybrid perovskite material (the perovskite layer), e.g., one with an ABX₃ crystal lattice where ‘A’ and ‘B’ are two cations of very different sizes, and X is an anion that coordinates to both cations. A perovskite solution typically includes an appropriate set of perovskite precursor materials and one or more solvents in which the precursor material is dissolved or suspended. A perovskite solution may also contain additives, e.g., to aid in crystal growth or to modify crystal properties or for some other purpose. A perovskite precursor material is typically an ionic species where at least one of its constituents becomes incorporated into the final perovskite layer ABX₃ crystal lattice. Organic perovskite precursor materials are materials whose cation contains carbon atoms while inorganic perovskite precursor materials are materials whose cation contains metal but does not contain carbon.

When the perovskite solution dries, perovskite crystals or an intermediate precursor phase for hybrid perovskite crystals (intermediate phase) form. The intermediate phase is a crystal, adduct, or mesophase that is not the desired final crystal lattice, which is ABX₃. The intermediate phase, if present, may be converted to the desired final crystal lattice by annealing. In some cases, annealing or other heating methods may include the use of heated nip rollers, optionally under nitrogen.

Some non-limiting examples of inorganic perovskite precursor materials for making perovskite solutions may include lead (II) iodide, lead (II) acetate, lead (II) acetate trihydrate, lead (II) chloride, lead (II) bromide, lead nitrate, lead thiocyanate, tin (II) iodide, rubidium halide, potassium halide, and cesium halide. In some cases, the halide may include iodide. Some non-limiting examples of organic perovskite precursor materials for making perovskite solutions may include methylammonium iodide, methylammonium bromide, methylammonium chloride, methylammonium acetate, formamidinium bromide, and formamidinium iodide. To produce a high-performance perovskite device, it is generally preferred in some cases that the organic perovskite precursor material has a purity greater than 99 percent by weight and the inorganic perovskite precursor has a purity greater than 99.9 percent by weight. The inorganic perovskite precursor material contains a metal cation, and in some preferred embodiments, the metal cation is lead. In some preferred embodiment, the molar ratio of organic perovskite precursor material to inorganic perovskite precursor material may be in a range of one to three.

In some cases, a perovskite solution may be formulated using a large proportion of a low boiling point solvent (e.g., at least 50 wt. % of total solvent, preferably at least 75 wt. % of total solvent, more preferably at least 90 wt. % of total solvent). In some embodiments, a low boiling point solvent is one having a boiling point of less than 150° C., or preferably less than 135° C. Such proportions may assist or enable high speed production of a uniform perovskite layer. Using an appropriate drying method, a low boiling point solvent can be made to evaporate quickly from the perovskite solution after deposition on a substrate thus minimizing movement of the crystals that form as the perovskite solution dries. Solvents that do not strongly coordinate with the perovskite precursors further enable short annealing times. Short annealing times are desirable because they enable higher production speeds. Alcohol-based solvents have been identified that do not strongly coordinate with the perovskite precursors, can provide the proper solubility of the inorganic precursors, and have been shown to produce a perovskite solution that can be stable for use in high volume manufacturing of perovskite layers and photovoltaic devices. Some non-limiting examples of alcohol-based solvents suitable for use at high proportions in the perovskite solution may include 2-methoxyethanol, 2-ethoxyethanol, 2-butoxyethanol, 2-isopropoxyethanol, methanol, propanol, butanol, and ethanol. Mixtures of solvents are envisioned for use in the perovskite solution to tune the evaporation profile to further optimize the drying process. Some non-limiting examples of suitable solvent additives useful for modifying evaporation rate of the solvent may include dimethylformamide, acetonitrile, dimethyl sulfoxide, N-methyl-2-pyrrolidone, dimethylacetamide, gamma-butyrolactone, phenoxyethanol, acetic acid, and urea.

In some preferred embodiments, a perovskite solution may be formulated with greater than 30 wt. % of solvent (e.g., 30-82 wt. %) and at least 18 wt. % of solids (e.g., 18-70 wt. %, preferably 25-60 wt. %, or 30-45 wt. %), where the total solids concentration of the perovskite solution is in a range of 30-70% by weight of its saturation concentration at the provided solution temperature. In some preferred embodiments, a solution temperature may be in a range of 20-50° C. In some preferred embodiments, the solvent is an alcohol and has a boiling point less than 135° C. In some preferred embodiments, the solvent is 2-methoxyethanol, which has a boiling point of 125° C. In some embodiments, such formulations may provide perovskite solutions that are stable at convenient handling and storage temperatures (e.g., in a range of 20-50° C., and in particular, room temperatures in a range of 20-25° C.), and which can be used to manufacture uniform perovskite layers at high speed, thereby enabling low-cost production of high efficiency solar cells with low equipment costs.

Although uniform perovskite layers have been made at high production speeds with the above formulations, it has sometimes been found that the time required for the perovskite solution to form homogeneous nuclei and grow may be longer than the time required to evaporate the low boiling point solvent in such a way as to produce a uniform perovskite layer. A uniform perovskite layer with optimum sized crystals is desired to make perovskite devices with high photovoltaic energy output. Addition of a crystal growth modifier added to a perovskite solution having a low boiling point solvent has been found to improve the performance of perovskite photovoltaic devices. A crystal growth modifier refers to an additive that either alters the amount of time for homogeneous crystal growth or alters the rate of homogeneous crystal growth when drying a perovskite solution. Some non-limiting examples of crystal growth modifiers that are especially useful in perovskite solutions for making high performance perovskite layers include dimethyl sulfoxide, N-methyl-2-pyrrolidone, gamma-butyrolactone, 1,8-diiodooctane, N-cyclohexyl-2-pyrrolidone, water, dimethylacetamide, acetic acid, cyclohexanone, alkyl diamines, and hydrogen iodide. In some preferred embodiments, the concentration of a crystal growth modifier may be less than about 10% by weight of the coating solution (e.g., in a range of 0.01-10% wt.). In some cases, a more preferred concentration of crystal growth modifier may be less than about 2% by weight of the coating solution (e.g., 0.01 to 2% wt.).

Another additive for a perovskite solution that may improve the performance of perovskite devices is a crystal grain boundary modifier. A crystal grain boundary modifier refers to an additive that improves the quality of the grain boundary, for example, be altering the electrical properties of the perovskite crystal grain boundary or reducing trap states at perovskite crystal grain boundary interfaces. Some non-limiting examples of crystal grain boundary modifiers that can be particularly useful in perovskite solutions for making high performance perovskite layers include choline chloride, phenethylamine, hexylamine, 1-α-phosphatidylcholine, polyethylene glycol sorbitan monostearate, sodium dodecyl sulfate, Poly(methyl methacrylate), Polyethylene glycol, pyridine, thiophene, ethylene carbonate, propylene carbonate, fullerenes, poly(propylene carbonate), and didodecyldimethylammonium bromide. A preferred concentration of crystal grain boundary modifier may be less than about 10% by weight of the coating solution (e.g., in a range of 0.01-10% wt.). In some cases, a more preferred concentration of crystal growth modifier may be less than about 2% by weight of the coating solution (e.g., 0.01 to 2% wt.).

### Electrodes

At least one of the top and bottom electrodes is transparent. In some embodiments, at least the top electrode is transparent. In some cases both the top and bottom electrodes are transparent (or one is transparent and the other is partially transparent) and the PV module may be a bifacial device. An electrode may be a single layer of electrically conductive material or have a multilayer structure. If transparency is not required, then the electrode may optionally include a non-transparent metal layer. A non-transparent metal layer for the bottom or top electrode may include, for example, silver, copper, gold, aluminum, molybdenum, tungsten, zinc, nickel, iron, tin, palladium, platinum, titanium, or alloys containing one or more of these metals. Non-transparent electrodes may be deposited from solution (e.g., coating, printing, electrodeposition), or alternatively, deposited using a physical vapor deposition method (e.g., sputtering or evaporation), or even a chemical vapor deposition method. In some cases, a solution deposition method may be preferred for high-speed manufacturing.

If transparency is desired for the electrode, there are several options. In some cases, a single layer or a multilayer of substantially transparent conductive material may be applied. In some cases, a transparent composite conductor may be used. A transparent composite conductor includes a transparent conducting layer and a pattern of metal (non-transparent) lines. The pattern of metal lines may be provided over the transparent conductor layer, or the transparent conducting layer may instead be provided over the pattern of metal lines. In some embodiments, the former may be preferred for forming a top electrode that is a transparent composite conductor (“top composite conductor”) and the latter may be preferred for forming a bottom electrode that is a transparent composite conductor (“bottom composite conductor”).

Below is a further discussion of methods and materials for forming a composite conductor, but it should be appreciated that the materials and method for forming the transparent conducting layer can generally be applied to any transparent electrodes that do not include the metal lines.

### Composite Conductors

The transparency of a composite conductor depends on the width of the metal lines (which are mostly opaque), the transparency of the conducting layer, may also depend in part on the layers adjacent the composite conductors, e.g., on their index of refraction.

### Transparent Conducting Layers

In some embodiments, a transparent conducting layer or transparent electrode may include a conductive polymer material such as PEDOT:PSS, a poly(pyrrole), a polyaniline, a polyphenylene, or a poly(acetylene). Conductive polymers may be applied by a coating from a suspension or solution, e.g., using any of the coating methods described above with respect to the perovskite absorbing layer. After coating, the conducting layer may optionally be subjected to heating or some other drying step to drive off solvent or otherwise improve conductivity properties of the conductive polymer.

In some embodiments, a transparent conducting layer or transparent electrode may include high aspect ratio metal nanowires (e.g., silver nanowires) or carbon nanotubes. Such materials may be coated from a dispersion (optionally with a binder) at a density sufficient to form an interconnected, conductive mesh, but low enough to achieve a desired transparency. After coating, the conducting layer may optionally be subjected to heating or some other drying step to drive off solvent or otherwise improve conductivity properties of the metal nanowires or carbon nanotubes.

In some preferred embodiments, a transparent conducting layer or transparent electrode may include doped or undoped metal oxides such as tin oxide (e.g., doped with indium or fluorine), molybdenum oxide, and zinc oxide (e.g., doped with aluminum). Such metal oxides are sometimes referred to as transparent conductive oxides (TCOs). TCOs may in some cases be coated from a suspension of metal oxide particles or formed from a sol-gel precursor solution, typically followed by a heating step to drive off solvent and anneal or sinter the metal oxide particles. TCOs may in some cases be deposited using dry deposition methods such as sputtering, physical vapor deposition, chemical vapor deposition, atomic layer deposition, e-beam deposition, or the like. In some preferred embodiments, a TCO may be deposited from an aerosol of nanoparticles (also considered a dry process). Some non-limiting examples of aerosol-based deposition are described in U.S. Pat. No. 10,092,926, which is incorporated by reference herein in its entirety for all purposes. In some cases, aerosol deposition may be less damaging to underlying device layers. A heating step may optionally follow such dry deposition processes, e.g., to improve conductivity of the deposited layer.

In some preferred embodiments, the conducting layer may be interposed between the metal line and a charge carrier layer. Such an arrangement has been found to reduce migration of metal and/or halide ions into the active portion of the perovskite photovoltaic structure. Such migration may cause degradation of performance over time. In some particularly preferred embodiments, the interposing conducting layer includes a TCO as described previously, e.g., indium-doped tin oxide (ITO) or aluminum doped zinc oxide (AZO). The TCO conducting layer may act as a barrier layer to diffusion of the metal and/or halide ions.

In some embodiments, the applied conducting layer may have an intrinsic sheet resistance (i.e., as measured in the absence of metal lines) of less than 1000 Ω/square, preferably less than 300 Ω/square. In some embodiments, the conducting layer may have an intrinsic sheet resistance in a range of 200 to 1000 Ω/square. While lower resistance is generally favored, in some embodiments, this range provides a practical balance of resistance with optical transparency. In some embodiments, the conducting layer may have a % T within a target wavelength range of at least 80%, alternatively at least 90%, at least 95%, or at least 97% (as measured in the absence of the metal lines). In some embodiments, the second conducting layer may have an absorptance % A within a target wavelength range of less than 20%, alternatively, less than 10%, less than 5%, or less than 3%.

The thickness of a conducting layer or transparent electrode depends in part on the electrical and optical properties of the selected material and may also depend on the deposition method. In some embodiments, the conducting layer may have a thickness of less than 500 nm, alternatively less than 200 nm, alternatively less than 100 nm, alternatively less than 50 nm, alternatively less than 20 nm, or alternatively less than 10 nm. In some embodiments, the conducting layer may be an aerosol-applied TCO having an average thickness in a range of 30 nm to 100 nm. When a conducting layer is applied over a set of metal lines, the average thickness may correspond to areas between the metal lines. When applied over metal lines, it is desirable in many cases that the conducting layer also substantially covers the metal lines to help ensure electrical continuity and prevent or reduce migration of metal ions into the active layers. In some cases, a surface energy modifying treatment may be applied to the substrate and a bottom set of metal lines to assist in adhesion and/or uniform deposition of the first conducting layer over both the substrate and the metal lines.

### Metal Lines

There is no particular limitation on the metal material that may be used for the metal lines. In some embodiments, the metal lines may include silver or copper, or alloys containing one or both of these metals. In some cases, other metals may be suitable including, but not limited to, gold, aluminum, molybdenum, tungsten, zinc, nickel, iron, tin, palladium, platinum, titanium, and alloys containing one or more of these metals. In some embodiments, the metal lines may be formed of a metal material having a conductivity of at least 105 S/m.

In some embodiments, metal lines may be deposited using a dry metal deposition process coupled with some patterning process. For example, metal lines may be deposited by thermal evaporation, sputtering, physical vapor deposition, chemical vapor deposition, atomic layer deposition, e-beam deposition, or the like. Patterned metal lines may be formed, for example, by deposition through a shadow mask or by using known photolithographic methods that may involve etching and/or lift-off processes. In some embodiments, a metal layer may be electrochemically or electrolessly deposited and then patterned into metal lines, for example, by photolithography. In some embodiments, metal lines may be deposited by transfer of prepatterned metal lines from a donor sheet to the intended surface, optionally in combination with heat and/or pressure.

In some embodiments, metal lines may be formed by printing. In some embodiments, printing may involve patterned application of an electroless metallization catalyst (e.g., palladium) followed by contact with an electroless plating solution (e.g., copper or nickel). In some preferred embodiments, metal lines may be printed using a metal-containing fluid mixture or “metal ink” (e.g., a suspension, slurry, paste, or the like). In some cases, printing metal lines may be performed by flexographic printing, inkjet printing, gravure printing, or some other printing technology. The printed metal lines may in some cases be followed by a heat treatment to drive off solvent or cause metal particles to fuse or sinter, which can increase the metal conductivity. Heat treatments may include an oven, IR heaters, flashlamps, heated rollers (with or without pressure), or the like. U.S. Pat. No. 8,907,258, incorporated herein by reference for all purposes, discloses a non-limiting example of a pulsed radiation apparatus that may be suitable for metal particle sintering in a roll-to-roll manner. In some cases, a printed metal ink may be subjected to a secondary chemical treatment such as a reducing agent. The metal ink may include metal particulates of various shapes and sizes (e.g., spherical, oblong, nanoparticles, nanowires) in an appropriate liquid carrier and may further include other agents such as binders, surfactants, or the like. A few non-limiting examples of metal inks may include those disclosed in US20220025200, which is incorporated herein by reference for all purposes. In some embodiments, a surface receiving the metal ink may first be treated to modify its surface energy, e.g., by corona discharge, a plasma, UV/ozone, or a chemical treatment. Modification of this surface energy can in some cases be used to control the shape, dimension, and/or adhesion of the deposited metal ink.

It should be appreciated that the inks, materials, and printing methods discussed above with respect to the metal lines may be similar to those used to make an electrically conductive connector.

The particular set of metal materials and patterning methods may be different for a bottom set of metal lines relative to a top set of metal lines. For example, if forming a bottom set of metal lines, the substrate may have a relatively wide tolerance for ink solvents, plating, photolithography, heat treatments, surface treatments, and the like. However, if forming a top set of metal lines the top conducting layer and underlying charge transport and perovskite layers may have a lower tolerance for these materials and treatments. In some embodiments, a set of top metal lines may be preferably formed using technology other than photolithography or plating.

A metal line may be characterized in cross section by a height (or thickness, e.g., in a Z axis) and width. Height and width may be measured at a particular point or may be reported as an average height and average width along a metal line. In some embodiments, the height or width may vary along the length of a metal line. A metal line cross-section may take on a variety of shapes and sizes. For example, a metal line may have a hemispherical shape in cross-section. Alternatively, a metal line may have a square, rectangular, trapezoidal, or some other polygonal shape in cross section. A set of metal lines may be characterized by an average spacing. In some preferred embodiments, the metal lines may be substantially parallel to each other and uniformly spaced (e.g., as shown for the set of top electrodes in FIGS. 1A, 1B, 2A, 2B, 3A, and 3B). “Substantially parallel lines” may refer to non-intersecting lines that, relative to a common axis along a length dimension, generally align within 30 degrees of each other, alternatively within 15 degrees, 10 degrees, 5 degrees, 3 degrees, 2 degrees, or even within 1 degree. “Uniformly spaced” may refer to an average standard deviation of the spacings that is less than about 20% of an average spacing. The metal lines may be substantially parallel to the X axis in these figures. When using roll-to-roll coating, such metal lines may be advantageously provided having a direction substantially orthogonal to the web conveyance direction, e.g., when using flexographic printing methods for the metal lines. In some cases, however, the metal lines may be provided at a different angle, or at various angles. Similarly, in some cases, the spacing may not be uniform. Although shown as straight lines, the metal lines could include some curvature or a zig-zag pattern. In some cases, a set of metal lines may include a cross-hatch grid pattern.

In some embodiments, a set of metal lines (top or bottom) occupies less than 15% of the active cell surface area, preferably less than 10%, more preferably less than 5%. In some cases, a set of metal lines occupies an active cell surface area in a range of 0.5% to 10%, or alternatively 1 to 5%. In some cases, the average spacing of the metal lines is in a range of 0.1 to 2.0 mm. In some cases, a ratio of average spacing of the metal lines to the average width of the metal lines is in a range of 10 to 100. In some embodiments, the average width of the metal lines of a set of metal lines is less than 40 μm, preferably less than 30 μm. In some embodiments, the average width of the metal lines of the top or bottom set of metal lines may be in a range of 1 to 30 μm, alternatively 2 to 25 μm. In some embodiments, the average height of the metal lines of a set of metal lines is at least 50 nm, preferably at least 100 nm.

In some embodiments, when both the top and bottom electrodes use transparent composite conductors, the bottom set of metal lines may be different in some way relative to the top set of metal lines, besides the location in the photovoltaic stack. In some cases, this difference may be with respect to at least one physical dimension (spacing, height, width, line direction, any ratios thereof, or the like). With respect to physical dimensions, such difference may be at least 5%, alternatively at least 10%, alternatively at least 20%, or alternatively at least 50%. For example, the spacings between at top set of metal lines may be different than the spacings of a bottom set of metal lines. In some embodiments, the average width of a bottom set of metal lines may be in a range of 15 to 40 μm, whereas an average width of a top set of metal lines may be in a range of 2 to 20 μm. In some printing embodiments, the width of the metal lines may in part be controlled by adjusting the surface energy of the surface on which they are printed. For example, matching a surface energy to an ink may allow for more spreading of the ink and produce wider lines. A mismatch in surface energy may reduce the amount of ink spreading and produce narrower lines.

In some embodiments, an average height of a set of bottom metal lines may be less than 300 nm, preferably less than 200 nm, more preferably less than 150 nm. For example, in some cases the average height of a set of bottom metal lines may be in a range of about 20-200 nm, alternatively in a range of 50-150 nm. In some cases, a set of top metal lines may have a height of greater than 50 nm, alternatively greater than 100 nm, alternatively greater than 200 nm, or alternatively greater than 500 nm. For example, in some cases an average a set of top metal lines may be in a range of 200-1500 nm. In some embodiments when printing a set of top metal lines, it may be difficult to fully sinter the metal without damaging the underlying perovskite or other layers. As such, the intrinsic resistivity of the metal line material may be higher than for a fully sintered metal line material. In such cases it may be preferred to deposit a thicker metal line to compensate.

Still further embodiments herein include the following enumerated embodiments.
1. A method of making a photovoltaic module including multiple photovoltaic cells connected in series, the method including:
a) providing a module precursor structure including:
   i) a substrate;
   ii) a bottom electrode overlaying the substrate;
   iii) a photoactive layer overlaying the bottom electrode, the photoactive layer including at least a perovskite absorber layer; and
   iv) a top electrode overlaying the photoactive layer, wherein at least one of the top and bottom electrodes is a transparent electrode;
b) forming at least one megascribe along a first dimension of the module precursor structure to define first and second photovoltaic cells, wherein forming the megascribe includes:
   i) removing the top electrode and photoactive layer in an upper scribe portion of the megascribe; and
   ii) removing the bottom electrode in a lower scribe portion of the megascribe;
c) forming a first insulating material along an edge of the first photovoltaic cell defined by the megascribe and forming a second insulating material along an edge of the second photovoltaic cell defined by the megascribe, wherein at least a portion of the bottom electrode corresponding to the second photovoltaic cell is not covered by either the first or second insulating materials; and
d) making a series connection between the first and second photovoltaic cells by forming an electrically conductive connector onto a portion of the top electrode of the first photovoltaic cell, over the first insulating material, and onto the portion of the bottom electrode of the second photovoltaic cell.
2. The method of embodiment 1, wherein step b(i) is performed before, after, or concurrently with step b(ii).
3. The method of embodiment 1 or 2, wherein the at least one megascribe is formed at least in part by laser etching.
4. The method of embodiment 3, wherein the laser etching includes a single laser etching event or multiple laser etching events.
5. The method of embodiment 3 or 4, wherein the laser etching includes the use of a nanosecond laser.
6. The method according to any of embodiments 3-5, wherein the laser etching includes the use of a picosecond laser.
7. The method according to any of embodiments 3-6, wherein the laser etching includes the use of a femtosecond laser.
8. The method according to any of embodiments 3-7, wherein the laser etching includes impingement of one or more laser beams through a top side of the module precursor structure.
9. The method according to any of embodiments 3-8, wherein the laser etching includes impingement of one or more laser beams through the substrate side of the module precursor structure.
10. The method according to any of embodiments 1-9, wherein forming the at least one megascribe is performed under an inert atmosphere.
11. The method according to any of embodiments 1-10, wherein the upper scribe portion has an average width in a range of 50 to 250 μm.
12. The method according to any of embodiments 1-11, wherein at least one of forming the first insulating material and forming the second insulating material includes inkjet deposition of an insulator ink.
13. The method according to any of embodiments 1-12, wherein at least one of forming the first insulating material and forming the second insulating material includes UV-curing of an insulator ink.
14. The method according to any of embodiments 1-13, wherein forming the first insulating material and forming the second insulating material are performed under an inert atmosphere.
15. The method according to any of embodiments 1-14, wherein forming the electrically conductive connector includes inkjet deposition of a conductive ink.
16. The method according to any of embodiments 1-15, wherein forming the electrically conductive connector includes photonic sintering of a conductive ink.
17. The method according to any of embodiments 1-16, wherein forming the electrically conductive connector includes sintering of a conductive ink by infrared radiation.
18. The method according to any of embodiments 1-17, wherein forming the electrically conductive connector includes sintering of a conductive ink by heating in an oven or contact with a heated gas.
19. The method according to any of embodiments 1-18, wherein forming the electrically conductive connector is performed under an inert atmosphere.
20. The method according to any of embodiments 1-19, wherein the module precursor structure is in the form of a web made by roll-to-roll manufacturing.
21. The method according to any of embodiments 1-19, wherein the module precursor structure is in the form of a cut sheet.
22. The method according to any of embodiments 1-21, wherein step (b) and step (c) are performed in sequence at a common interconnect processing station, and further including forming an additional megascribe which defines additional photovoltaic cells in a module precursor structure at the common interconnect processing station concurrently with forming of the first and second insulating materials along the edges of the first and second photovoltaic cells.
23. The method according to any of embodiments 1-22 wherein step (c) and step (d) are performed in sequence at a common interconnect processing station, and further including forming an additional insulating material along an edge of an additional photovoltaic cell in a module precursor structure at the common interconnect processing station concurrently with forming of the electrically conductive connector making a series connection between the first and second photovoltaic cells.
24. The method according to any of embodiments 1-23, wherein the electrically conductive connector includes copper.
25. The method according to any of embodiments 1-24, wherein the electrically conductive connector includes silver.
26. The method according to any of embodiments 1-25, wherein the photoactive layer includes a first carrier transport layer disposed between the perovskite absorber layer and the bottom electrode and a second carrier transport layer disposed between the perovskite absorber layer and the top electrode.
27. The method according to any of embodiments 1-26, wherein the top electrode is transparent.
28. The method of embodiment 27, wherein the top electrode is a composite conductor including a transparent top conducting layer disposed over the photoactive layer and a set of top metal lines disposed over the transparent top conducting layer.
29. The method of embodiment 28, wherein the composite conductor includes a first region including a first set of top metal lines and a second region including a second set of top metal lines, wherein a space between the first region and the second region defines a process target region where there are no top metal lines, and wherein the at least one megascribe is formed within the process target region.
30. The method of embodiment 28 or 29, wherein the transparent top conducting layer includes a conductive metal oxide having a thickness of less than 100 nm, and the top metal lines have an average height of at least 100 nm.
31. The method according to any of embodiments 28-30, wherein the top metal lines include silver.
32. The method according to any of embodiments 28-31, wherein the top metal lines include copper.
33. The method according to any of embodiments 28-32, wherein the top metal lines are aligned in a second dimension substantially orthogonal to the first dimension, and wherein the top metal lines are substantially parallel to each other and include an average spacing in a range of 0.1 to 2.0 mm.
34. The method according to any of embodiments 1-33, wherein the bottom electrode is transparent.
35. The method of embodiment 34, wherein the bottom electrode is a composite conductor including a set of bottom metal lines disposed over the substrate and a transparent bottom conducting layer interposed between the bottom metal lines and the photoactive layer.
36. The method according to any of embodiments 1-35, further including forming a second megascribe spaced from, and parallel to, the at least one megascribe to define a third photovoltaic cell adjacent to the second photovoltaic cell.
37. The method of embodiment 36, wherein the at least one megascribe is characterized by a first megascribe width measured along a second dimension substantially orthogonal to the first dimension, and the distance between one edge of the at least one megascribe and a corresponding edge of the second megascribe is at least 10 times larger than the first megascribe width.
38. The method according to any of embodiments 1-37, wherein the at least one megascribe and any additional megascribes formed in the module precursor structure collectively occupy a total megascribe area that is less than 10% of the area of the resulting photovoltaic module.
39. The method according to any of embodiments 1-35, wherein the first and second insulating materials include a polymer, a silicone, a ceramic, a non-conductive metal oxide, a carbon nitride, or a graphene oxide, or a combination thereof.
40. A photovoltaic module including:
a) a substrate;
b) a first photovoltaic cell provided over the substrate and a second photovoltaic cell provided over the substrate and adjacent to the first photovoltaic cell, wherein the first and second photovoltaic cells each independently include:
   i) a bottom electrode overlaying the substrate;
   ii) a photoactive layer overlaying the bottom electrode, the photoactive layer including at least a perovskite absorber layer; and
   iii) a top electrode overlaying the photoactive layer, wherein at least one of the top and bottom electrodes is a transparent electrode;
c) a megascribe extending along a first dimension of the photovoltaic module and defining an edge of the first photovoltaic cell and an edge of the second photovoltaic cell, the megascribe including:
   i) an upper scribe portion separating the photoactive layer and the top electrode of the first photovoltaic cell from the respective photoactive layer and top electrode of the second photovoltaic cell; and
   ii) a lower scribe portion separating the bottom electrode layer of the first photovoltaic cell from the bottom electrode layer of the second photovoltaic cell;
d) a first insulating material disposed over the edge of the first photovoltaic cell and a second insulating material disposed over the edge of the second photovoltaic cell; and
e) a series connection between the first and second photovoltaic cells, the series connection including an electrically conductive connector provided in contact with a portion of the top electrode of the first photovoltaic cell, over the first insulating material, and in contact with the bottom electrode of the second photovoltaic cell.
41. The photovoltaic module of embodiment 40, wherein the upper scribe portion has an average width in a range of 50 to 250 μm.
42. The photovoltaic module of embodiment 40 or 41, wherein the electrically conductive connector includes silver.
43. The photovoltaic module according to any of embodiments 40-42, wherein the electrically conductive connector includes copper.
44. The photovoltaic module according to any of embodiments 40-43, wherein the photoactive layer includes a first carrier transport layer disposed between the perovskite absorber layer and the bottom electrode and a second carrier transport layer disposed between the perovskite absorber layer and the top electrode.
45. The photovoltaic module according to any of embodiments 40-44, wherein the top electrode is transparent.
46. The photovoltaic module of embodiment 45, wherein the top electrode is a composite conductor including a transparent top conducting layer disposed over the photoactive layer and a set of top metal lines disposed over the transparent top conducting layer.
47. The photovoltaic module of embodiment 46, wherein the transparent top conducting layer includes a conductive metal oxide having a thickness of less than 100 nm and the top metal lines have an average height of at least 100 nm.
48. The photovoltaic module according to any of embodiments 46-47, wherein the top metal lines include silver.
49. The photovoltaic module according to any of embodiments 46-48, wherein the top metal lines include copper.
50. The photovoltaic module according to any of embodiments 46-49, wherein the top metal lines are aligned in a second dimension substantially orthogonal to the first dimension, and wherein the top metal lines are substantially parallel to each other and include an average spacing in a range of 0.1 to 2.0 mm.
51. The photovoltaic module according to any of embodiments 40-50, wherein the bottom electrode is transparent.
52. The photovoltaic module of embodiment 51, wherein the bottom electrode is a composite conductor including a set of bottom metal lines disposed over the substrate and a transparent bottom conducting layer interposed between the bottom metal lines and the photoactive layer.
53. The photovoltaic module according to any of embodiments 40-52, further including a second megascribe defining a third photovoltaic cell adjacent to the second photovoltaic cell.
54. The photovoltaic module of embodiment 53, wherein the at least one megascribe is characterized by a first megascribe width measured along a second dimension substantially orthogonal to the first dimension, and the distance between one edge of the at least one megascribe and a corresponding edge of the second megascribe is at least 10 times larger than the first megascribe width.
55. The photovoltaic module according to any of embodiments 40-54, wherein the at least one megascribe and any additional megascribes in the photovoltaic module collectively occupy a total megascribe area that is less than 10% of the area of the photovoltaic module.
56. The photovoltaic module according to any of embodiments 40-55, wherein the first and second insulating materials include a polymer, a silicone, a ceramic, a non-conductive metal oxide, a graphene oxide, or a carbon nitride, or a combination thereof.

The specific details of particular embodiments may be combined in any suitable manner without departing from the spirit and scope of embodiments of the invention. However, other embodiments of the invention may be directed to specific embodiments relating to each individual aspect, or specific combinations of these individual aspects.

The above description of example embodiments of the invention has been presented for the purposes of illustration and description. It is not intended to be exhaustive or to limit the invention to the precise form described, and many modifications and variations are possible in light of the teaching above.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having described several embodiments, it will be recognized by those of skill in the art that various modifications, alternative constructions, and equivalents may be used without departing from the spirit of the invention. Additionally, a number of well-known processes and elements have not been described in order to avoid unnecessarily obscuring the present invention. Additionally, details of any specific embodiment may not always be present in variations of that embodiment or may be added to other embodiments. It should be noted that, unless otherwise explicitly noted or required by context, the word “or” is used in this disclosure in a non-exclusive sense.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither, or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a method” includes a plurality of such methods and reference to “the device” includes reference to one or more devices and equivalents thereof known to those skilled in the art, and so forth. The invention has now been described in detail for the purposes of clarity and understanding. However, it will be appreciated that certain changes and modifications may be practice within the scope of the appended claims.

All publications, patents, and patent applications cited herein are hereby incorporated by reference in their entirety for all purposes. None is admitted to be prior art.

1. A method of making a photovoltaic module comprising multiple photovoltaic cells connected in series, the method comprising:
a) providing a module precursor structure comprising:
i) a substrate;
ii) a bottom electrode overlaying the substrate;
iii) a photoactive layer overlaying the bottom electrode, the photoactive layer comprising at least a perovskite absorber layer; and
iv) a top electrode overlaying the photoactive layer,
wherein at least one of the top and bottom electrodes is a transparent electrode;
b) forming at least one megascribe along a first dimension of the module precursor structure to define first and second photovoltaic cells, wherein forming the megascribe comprises:
i) removing the top electrode and photoactive layer in an upper scribe portion of the megascribe; and
ii) removing the bottom electrode in a lower scribe portion of the megascribe,
c) forming a first insulating material along an edge of the first photovoltaic cell defined by the megascribe and forming a second insulating material along an edge of the second photovoltaic cell defined by the megascribe, wherein at least a portion of the bottom electrode corresponding to the second photovoltaic cell is not covered by either the first or second insulating materials, and wherein the first and second insulating materials are transparent to visible light; and
d) making a series connection between the first and second photovoltaic cells by forming an electrically conductive connector onto a portion of the top electrode of the first photovoltaic cell, over the first insulating material, and onto the portion of the bottom electrode of the second photovoltaic cell.

2. The method of claim 1, wherein step b(i) is performed concurrently with step b(ii).

3. The method of claim 1, wherein the at least one megascribe is formed at least in part by laser etching, and wherein the laser etching comprises a single laser etching event.

4-10. (canceled)

11. The method of claim 1, wherein the upper scribe portion has an average width in a range of 50 to 250 μm.

12. The method of claim 1, wherein at least one of forming the first insulating material and forming the second insulating material comprises inkjet deposition of an insulator ink.

13. The method of claim 1, wherein at least one of forming the first insulating material and forming the second insulating material comprises UV-curing of an insulator ink, and wherein forming the first insulating material and forming the second insulating material are performed under an inert atmosphere.

14. (canceled)

15. The method of claim 1, wherein forming the electrically conductive connector comprises inkjet deposition of a conductive ink, and wherein forming the electrically conductive connector comprises i) photonic sintering of the conductive ink, or ii) sintering the conductive ink by heating in an oven or contact with a heated gas.

16-19. (canceled)

20. The method of claim 1, wherein the module precursor structure is in the form of a web made by roll-to-roll manufacturing.

21. (canceled)

22. The method of claim 1, wherein step (b) and step (c) are performed in sequence at a common interconnect processing station, and further comprising forming an additional megascribe which defines additional photovoltaic cells in a module precursor structure at the common interconnect processing station concurrently with forming of the first and second insulating materials along the edges of the first and second photovoltaic cells.

23. The method of claim 1, wherein step (c) and step (d) are performed in sequence at a common interconnect processing station, and further comprising forming an additional insulating material along an edge of an additional photovoltaic cell in a module precursor structure at the common interconnect processing station concurrently with forming of the electrically conductive connector making a series connection between the first and second photovoltaic cells.

24-27. (canceled)

28. The method of claim 1 wherein the top electrode is a composite conductor comprising a transparent top conducting layer disposed over the photoactive layer and a set of top metal lines disposed over the transparent top conducting layer.

29. The method of claim 28, wherein the composite conductor comprises a first region comprising a first set of top metal lines and a second region comprising a second set of top metal lines, wherein a space between the first region and the second region defines a process target region where there are no top metal lines, and wherein the at least one megascribe is formed within the process target region.

30. The method of claim 28, wherein the transparent top conducting layer comprises a conductive metal oxide having a thickness of less than 100 nm, and the top metal lines have an average height of at least 100 nm.

31. (canceled)

32. (canceled)

33. The method of claim 28, wherein the top metal lines are aligned in a second dimension substantially orthogonal to the first dimension, and wherein the top metal lines are substantially parallel to each other and comprise an average spacing in a range of 0.1 to 2.0 mm.

34. (canceled)

35. The method of claim 1 wherein the bottom electrode is a composite conductor comprising a set of bottom metal lines disposed over the substrate and a transparent bottom conducting layer interposed between the bottom metal lines and the photoactive layer.

40. A photovoltaic module comprising:
a) a substrate;
b) a first photovoltaic cell provided over the substrate and a second photovoltaic cell provided over the substrate and adjacent to the first photovoltaic cell, wherein the first and second photovoltaic cells each independently comprise:
i) a bottom electrode overlaying the substrate;
ii) a photoactive layer overlaying the bottom electrode, the photoactive layer comprising at least a perovskite absorber layer; and
iii) a top electrode overlaying the photoactive layer,
wherein at least one of the top and bottom electrodes is a transparent electrode;
c) a megascribe extending along a first dimension of the photovoltaic module and defining an edge of the first photovoltaic cell and an edge of the second photovoltaic cell, the megascribe comprising:
i) an upper scribe portion separating the photoactive layer and the top electrode of the first photovoltaic cell from the respective photoactive layer and top electrode of the second photovoltaic cell; and
ii) a lower scribe portion separating the bottom electrode layer of the first photovoltaic cell from the bottom electrode layer of the second photovoltaic cell;
d) a first insulating material disposed over the edge of the first photovoltaic cell and a second insulating material disposed over the edge of the second photovoltaic cell, wherein the first and second insulating materials are transparent to visible light; and
e) a series connection between the first and second photovoltaic cells, the series connection comprising an electrically conductive connector provided in contact with a portion of the top electrode of the first photovoltaic cell, over the first insulating material, and in contact with the bottom electrode of the second photovoltaic cell.

41-45. (canceled)

46. The photovoltaic module of claim 40, wherein the top electrode is a composite conductor comprising a transparent top conducting layer disposed over the photoactive layer and a set of top metal lines disposed over the transparent top conducting layer, and wherein the transparent top conducting layer comprises a conductive metal oxide having a thickness of less than 100 nm and the top metal lines have an average height of at least 100 nm.

47-51. (canceled)

52. The photovoltaic module of claim 40, wherein the bottom electrode is a composite conductor comprising a set of bottom metal lines disposed over the substrate and a transparent bottom conducting layer interposed between the bottom metal lines and the photoactive layer.

53-55. (canceled)

56. The photovoltaic module of claim 40, wherein the first and second insulating materials comprise a polymer, a silicone, a ceramic, a non-conductive metal oxide, a graphene oxide, or a carbon nitride, or a combination thereof.

57. The photovoltaic module of claim 40, wherein the first and second insulating materials act as blocking layers to reduce or prevent the ingress of unwanted ions or other compounds into or out of at least one photovoltaic cell.
